(19) United States
(12) Patent Application Publication
(10) Pub. No.: US 2008/0308154 A1
(43) Pub. Date: Dec. 18, 2008

(54) Reflective secondary optic for concentrated photovoltaic systems

(75) Inventors: Robert Cart, Berkeley, CA (US); Kevin Richard Fine, Redwood City, CA (US); Sandheep Kumar Surendran, San Francisco, CA (US)

Correspondence Address: VAN PELT, YI & JAMES LLP, 10050 N. FOOTHILL BLVD #200, CUPERTINO, CA, 95014, US

(73) Assignee: GREEN VOLTS, INC.

(21) Appl. No.: 12/156,948

(22) Filed: Jun. 4, 2008

Related U.S. Application Data
(60) Provisional application No. 60/933,341, filed on Jun. 6, 2007.

(51) Int. Cl. H01L 31/00

(52) U.S. Cl. 136/259

(57) ABSTRACT

A solar power system is disclosed. The solar power system includes: a solar energy receiving solar collector; a reflective secondary optical element comprising one or more sheets, wherein the one or more sheets are arranged to form a hollow structure having an interior surface, an exterior surface, an entry aperture, and an exit aperture, such that at least a portion of the interior of the hollow structure is reflective and wherein the hollow structure is positioned to receive energy from the solar collector through the entry aperture, reflect the energy from the interior surface of the hollow structure, and output the reflected energy through the exit aperture; and a receiver positioned to receive the reflected energy from the exit aperture. The energy from the solar collector is reflected and thereby directed through the exit aperture to the receiver by the reflective secondary optical element.

### CROSS REFERENCE TO OTHER APPLICATIONS

This application claims priority to U.S. Provisional Patent Application No. 60/933,341 (Attorney Docket No. GREEP007+) entitled REFLECTIVE SECONDARY OPTIC FOR CONCENTRATED PHOTOVOLTAIC SYSTEMS filed Jun. 6, 2007 which is incorporated herein by reference for all purposes.

### BACKGROUND OF THE INVENTION

Solar power systems include concentrating and non-concentrating systems. In non-concentrating solar power systems, the solar cell receives direct and indirect sunlight. An example of a non-concentrating solar power system is a flat panel of photovoltaic (PV) cells that directly receive sunlight. In concentrating solar power systems, the solar cell receives indirect sunlight that has been concentrated by a collector and directed at the receiver. An example of a concentrating solar power system is a parabolic collector in which a solar cell is located at the focus.

Solar power systems include tracking and non-tracking solar power systems. In a typical tracking system, a tracker is used to track the sun as it moves across the sky to maximize exposure of a collector to direct normal incidence (DNI) light from the sun. Existing commercialized planar tracker systems are designed for flat panel PV modules and are in largely small scale use. These trackers typically have a large rectangular panel that is maintained normal to the incident sunlight via pivots with gears and motors set atop a tall pole several meters in height. Having the entire panel turn to face the sun creates shading on adjacent trackers requiring that these trackers be placed at a greater distance apart to reduce shading. This reduces the energy density per unit land area achievable. Further, to allow for low sun elevation angles where the large panel is facing the horizon, the panels must be supported high off the ground to provide clearance. This requires larger scale materials, increases wind loading, and makes maintenance difficult and dangerous. Finally, a high degree of tracking accuracy is difficult due to the small moment arm of the drive mechanism, usually mounted atop the pole. Thus, improvements in solar power system design are needed.

In concentrated photovoltaic (CPV) systems, a secondary optic can be used to improve the overall acceptance angle of energy arriving at the collector. Secondary optics are typically solid glass or dielectric optics that are ground and polished or molded into a desired shape and then placed above the active surface of the solar cell. Such transmissive secondary optics are heavy and expensive to manufacture. For example, the grinding process is slow and molding requires an expensive tool to press it into shape. Cost can be on the order of several dollars per part. Transmissive secondary optics are also subject to fracturing from handling or due to thermal shock. In addition, there are transmission losses associated with transmissive secondary optics no matter which angle at which energy arrives at the collector. Improved secondary optics would be desirable.

### BRIEF DESCRIPTION OF THE DRAWINGS

Various embodiments of the invention are disclosed in the following detailed description and the accompanying drawings.

FIG. 1 is a diagram illustrating an embodiment of a solar power system.

FIG. 2 is a diagram illustrating an embodiment of a solar concentrating system.

FIG. 3 is a diagram illustrating an embodiment of solar power module 200 from the perspective of the sun.

FIG. 4A is a diagram illustrating an embodiment of a concentrating solar power system having a transmissive secondary optic as a secondary element.

FIG. 4B is a diagram illustrating an embodiment of a concentrating solar power system having a reflective secondary element.

FIG. 4C is a diagram illustrating an embodiment of a concentrating solar power system having a wavelength splitting secondary element.

FIG. 5A is a diagram illustrating an embodiment of multiple arrays of solar collectors.

FIG. 5B is a diagram illustrating an example of spacing between two rows.

FIG. 6A is a diagram illustrating an embodiment of a tracking platform that may be used to support one or more solar power modules.

FIG. 6B is a diagram illustrating an embodiment of a drive mechanism used to rotate a platform.

FIG. 6C is a diagram illustrating an embodiment of a drive mechanism used to rotate a platform.

FIG. 6D is a diagram illustrating an embodiment of a drive mechanism used to rotate a platform.

FIG. 6E is a diagram illustrating an embodiment of a drive mechanism used to rotate a platform.

FIG. 6F is a diagram illustrating an embodiment of a wheel and a track that are shaped to help prevent slippage of the wheel off the track.

FIG. 6G is a diagram illustrating an alternative embodiment of a tracking platform that may be used to support one or more solar power modules.

FIG. 6H is a diagram illustrating an embodiment of a tracking structure in which all the row structures are in a maintenance state.

FIG. 7A is a diagram illustrating an embodiment of a configuration used to wash one or more collectors.

FIG. 7B is a diagram illustrating an embodiment of a configuration used to wash one or more collectors when facing the aperture of the collectors.

FIG. 8 is a diagram illustrating an embodiment of a concentrating solar power system having a reflective secondary optic as a secondary element.

FIG. 9 is a diagram illustrating various views of an embodiment of a reflective secondary optic.

FIG. 10A is a diagram illustrating an embodiment of a cross section of a sheet from which the facets of secondary optic 924 are formed.

FIG. 10B is a diagram illustrating another embodiment of a cross section of a sheet from which the facets of secondary optic 924 are formed.

FIG. 11 is a diagram illustrating an embodiment of a secondary optic. This figure shows a close up of secondary optic 806 and receiver 804 in FIG. 8.

FIG. 12 is a diagram illustrating an embodiment of a concentrating solar power system having a reflective secondary optic that has a shield.

FIG. 13 is a diagram illustrating an embodiment of a concentrating solar power system having a reflective secondary optic that is enclosed in a protective box.

FIG. 14 is a diagram illustrating an embodiment of a concentrating solar power system having a reflective secondary optic and a collector, both are which are enclosed in a protective box.

FIG. 15 is a diagram illustrating various views of another embodiment of a reflective secondary optic.

FIG. 16 is a diagram illustrating various views of another embodiment of a reflective secondary optic.

FIG. 17A is a diagram illustrating various views of another embodiment of a reflective secondary optic.

FIG. 17B is a diagram illustrating various views of another embodiment of a reflective secondary optic.

FIG. 18A illustrates embodiments of an eight faceted reflective secondary optic.

FIG. 18B is a diagram illustrating various views of another embodiment of a reflective secondary optic.

FIG. 19A is a diagram illustrating an embodiment of a secondary optic that is curved in one dimension.

FIGS. 19B-19D show a front view, side view, and top view, respectively, of secondary optic 1902.

FIG. 20 is a diagram illustrating an embodiment of edge preparation in a secondary optic.

### DETAILED DESCRIPTION

The invention can be implemented in numerous ways, including as a process, an apparatus, a system, or a composition of matter. In this specification, these implementations, or any other form that the invention may take, may be referred to as techniques. A component such as a solar cell described as being configured to perform a task includes both a general component that is temporarily configured to perform the task at a given time or a specific component that is manufactured to perform the task. In general, the order of the steps of disclosed processes may be altered within the scope of the invention. As used herein, the term ‘cell’ or ‘solar cell’ refers to one or more devices that converts sunlight to electricity, such as a photovoltaic cell.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

An example of a concentrating solar power system is a parabolic collector with a solar cell located at the focus. A parabolic collector has a shape of a paraboloid of revolution. However, locating a solar cell at the focus of a parabolic collector means that the solar cell (and its supporting structure) shades the collector, reducing the effective aperture and efficiency of the system. One technique is to locate the solar cell so that it does not shadow the collector when the sun's rays hit the collector above a specified elevation (or altitude) angle of the sun relative to the position of the collector. For example, for a parabolic collector, the cell can be located such that it is not located along the focal axis of the parabola. (The focal axis is the line that intersects the vertex of the parabola and the focal point.) As used herein, if the cell is not centered along the focal axis of the parabola, then its location is referred to as “off-axis”.

An area focus solar collector focuses sunlight to a point or to an area. One application of an area focus solar collector is to focus sunlight onto the surface of a single discrete solar cell, an array of multiple solar cells, multiple cells responding to different wavelengths, or a solar thermal collector. An example of an area focus collector is a parabolic collector. A linear focus solar collector focuses sunlight onto a line, such as a pipe. An example of a linear focus solar collector is a solar thermal trough. As used herein, any collector that does not focus to a line is an area focus collector.

In some solar thermal energy systems, a plurality of linear focus collectors are mounted on a tracker platform. However, installing a plurality of area focus collector systems on a single tracker platform using typical area focus collector designs is impractical due to a much higher part count in typical area focus collector designs. It requires greater sophistication to make a unit with a higher part count viable. The higher number of parts increases the tolerance stack up, as well as the cost and difficulty of manufacturing. From a design point of view, it is much easier to make a single structure strong and stiff, and it is much harder to do this for an assembly of many smaller pieces. As such, typical area focus collector systems consist of a single large reflector on a tall tracker.

High concentration solar cells are typically small, are very fragile, have thin film coatings on their surface, and have electrical attachments. In high concentration PV (CPV) systems, the accuracy of the focus of the solar radiation collector on the cell, whether a reflective mirror or a refractive lens, with or without a secondary optic, is critical for generating the maximum amount of energy and therefore the cost-effectiveness of CPV systems. In order to do this, collector modules must be accurately assembled while protecting the fragile solar cell assembly as part of the larger, less fragile and mechanical concentration apparatus. Typically, maintaining accuracy of cell placement in relation to the flux field created by the concentration device requires assembling the modules in a facility with highly specialized training and tools. This is impractical for large scale installations.

Often, the trackers to which the modules are attached are large, heavy, steel or aluminum devices that require high installation cost due to concrete, cranes, and heavy equipment. For large scale solar power plants, this process must be repeated thousands of times carefully and accurately. CPV systems currently available show that the cell is permanently bonded to the structure of the collector module, mixing fragile and sturdy parts and risking breakage of the expensive cells. These cells must be wired in series in order to achieve maximum voltage prior to inversion and must be safe from short circuit, especially in moist conditions. Exposure to atmospheric conditions such as rain, wind, snow, hail, condensation, dust or wind-blown particulates, can reduce or damage the efficiency of the cell or the module.

In addition, high concentration PV cells function best in certain temperature ranges. However, the concentration of solar radiation generates large amounts of heat in the cells. The heat of concentration can damage or destroy the expensive cells. Even at lower temperatures, heat from concentration reduces the efficiency of the output from the cell. The cell assembly typically has a thermal management system like active cooling, such as circulated refrigerants, or adequate passive measures to allow for heat to be conducted away from the cells. Active cooling measures are complicated and expensive. Passive cooling requires that materials in contact with the cell assembly provide both conduction of heat away from the cell assembly and for dissipation of heat via the surface area of heat sinks into the air.

Over time, cells or cell assemblies will be damaged. Because PV cells are wired in series to achieve maximum voltage, a reduction in the output of a cell or cells in the series will dramatically reduce the output of the whole series. In a large CPV power plant, it must be possible to replace a cell assembly without the down time of removing an entire tracker with all of its modules to a lab, where a single cell assembly is replaced. In general, the process of replacing a cell assembly in the field would be done by a relatively unskilled worker, so the replacement process must be fast, accurate and easily accomplished. As the efficiency of the cells improves, it may become desirable to replace of all the cell assemblies in a way that would not require fundamental modification of the collector apparatus. One element of the cost effectiveness of CPV power plants depends on the ability to protect expensive solar cells during installation and use and to remove and replace them for maintenance and upgrade is disclosed.

Because of the high temperatures that may result from concentrated sunlight, a concentrating solar power system may include a thermal structure for removing waste heat from the solar power system. Thermal structures may be stacked behind the structure supporting the solar cell so as to avoid shading the collector. In this case, there is limited space available on the back of the structure supporting the solar cell, consequently limiting the ability to remove heat from the system. The reason that there is limited space in this case is because of the potential for shading the collector while trying to pack many units close together.

Tracking platforms, receiver and secondary element structures, thermal structures, and maintenance techniques are disclosed.

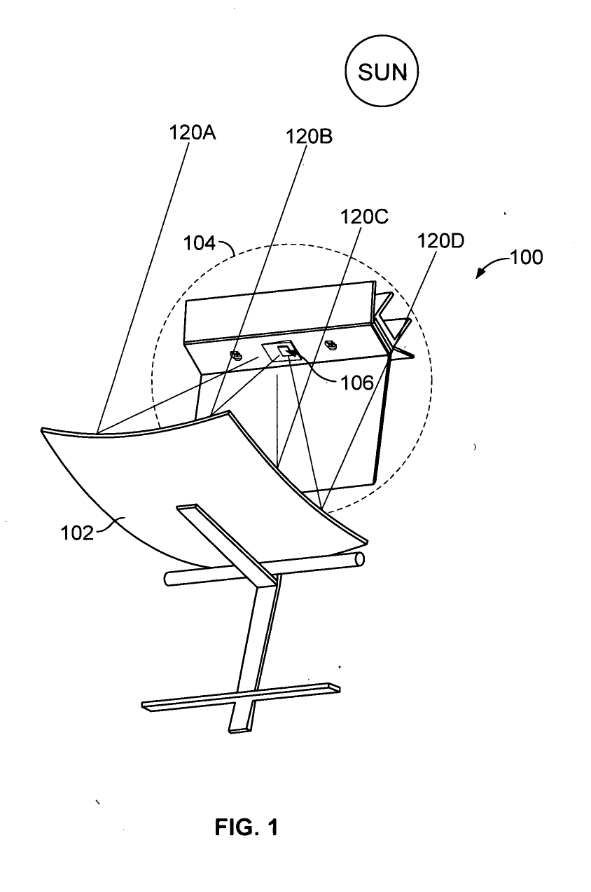

FIG. 1 is a diagram illustrating an embodiment of a solar power system. In this example, a concentrating solar power module 100 is shown. Concentrating solar power systems concentrate a larger area (aperture) exposed to the sun onto a smaller area where a receiver (or receivers), such as a solar cell or photovoltaic cell is located. Concentrating solar power systems include a collector, such as a reflector, mirror, or lens, for collecting and concentrating sunlight onto a receiver or target. The receivers could include a thermal collector(s) or a photovoltaic cell(s) in any band of the spectrum (e.g., visible light, infrared light, radio waves, etc.) or other solar radiation collection devices. Although solar cells may be described in the examples herein, any type of receiver may be used in various embodiments. Because of the high temperatures that result from concentrated sunlight, a solar power system may also include a thermal structure for removing heat from the solar power system.

In some embodiments, in a non-concentrating solar power system, the collector and the receiver are the same. For example, a flat panel of photovoltaic cells both collects incident solar energy and receives it for generation of electricity.

When using a solar collector in a concentrating system, solar cells developed for use with solar collectors, or CPV solar cells may be used. This is because the CPV solar cell is able to handle higher concentrations of sunlight in terms of electrical power conversion and heat. The cost of CPV solar cells is dropping and at the same time efficiency is increasing. High efficiency multi-junction PV cells, only recently available, promise high cell efficiencies approaching 40.7%—double that of crystalline silicon cells—with efficiencies of CPV modules approaching or exceeding 30%. Also, advances in efficient DC to AC inverters have been recently realized. With efficiency, speed of construction, ease of interconnection and the possibility of distributed generation, CPV is becoming an affordable and cost effective technology for large scale solar power plants.

In this example, solar power module 100 is shown to include collector 102, solar cell 106, and thermal structure 104. Collector 102 is a reflector in this example, but in other embodiments may be any appropriate collector. Sunlight 120A-D is received at collector 102 and reflected back towards solar cell 106 due to the shape of collector 102, as shown. Collector 102 may take any appropriate shape. In some embodiments, collector 102 is parabolic, spherical, curved, or another appropriate shape. Thermal structure 104 includes solar cell 106, which may be attached to thermal structure 104 using a receiver module, as more fully described below. Thermal structure 104 is able to spread and sink waste heat reflected off of collector 102 that is received at solar collector 106 and at thermal structure 104. In this example, thermal structure 104 includes a plurality of fins that function as heat sinks. In other embodiments, thermal structure 104 may have other heat spreading and/or heat sinking structures, as more fully described below.

In this example, thermal structure 104 is positioned such that sunlight received at collector 102 is not shadowed by thermal structure 104. In some embodiments, collector 102 is parabolic and thermal structure 104 is located off-axis from the line of focus of the parabola. Eliminating the shadowing by thermal structure 104 allows for sunlight to hit the full aperture of collector 102 and thus provides for greater efficiency.

In some embodiments, thermal structure 104 is fixed with respect to collector 102 and module 100 is configured to track the sun as it moves with time so that sunlight hits collector 102 at a constant angle during operation. For example, support 110 may be attached to a tracking platform, an example of which is provided below, that allows it to track the location of the sun.

Polished collectors made of mirrored glass, aluminum, or film coated plastic, carbon fiber, or other material, as well as lenses made of glass or plastic, including Fresnel lenses, can be used as a means for concentration of solar radiation. In various embodiments, the material(s) used in collector 102 include one or more of glass, plastic, aluminum, copper, steel, any metal, carbon fiber, any material either reflective by itself or coated with a reflective coating, and any material with suitable rigidity, stability and reflective properties, as a constituent part of a larger solar radiation collector module structure.

Alternative embodiments of the shape and size of collector 102 include collectors of various dimensions and focal lengths designed to concentrate solar radiation into a flux field with the properties and shape of the solar cell or heat collection device employed in the module. This could include linear or closely packed groupings of cells or heat collection devices for line focus collectors.

The same form of collector can be used in an alternative embodiment that directs solar radiation onto a heat collection device used to transfer the heat to a fluid, which is then circulated from the tracker for use in the generation of electricity, the production of hydrogen or for heating or cooling.

As shown, thermal structure 104 is used both as a heat transfer mechanism and as a mechanical structural element, providing rigidity for the structure and a location and position for solar cell 106. Solar cell 106 may thus be correctly aligned using thermal structure 104.

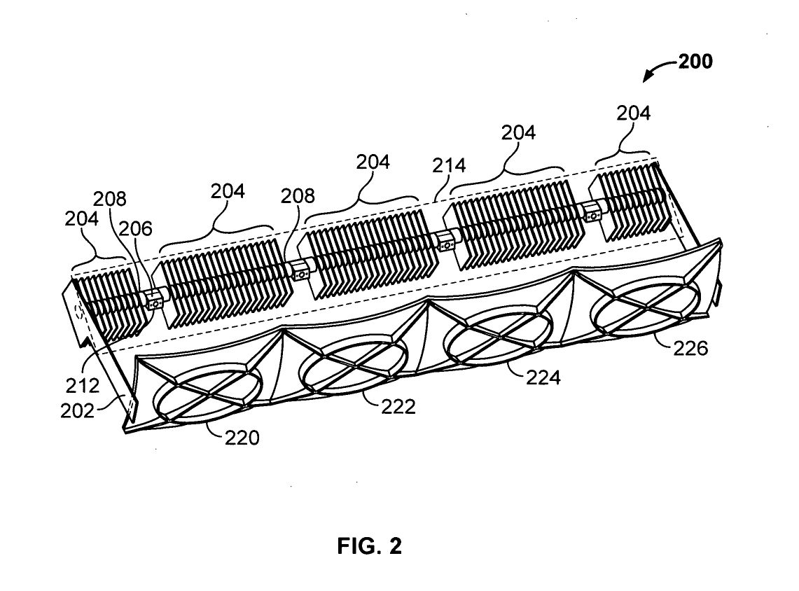

FIG. 2 is a diagram illustrating an embodiment of a solar concentrating system. In this example, solar concentrating module 200 includes an array of four solar collectors. As shown, support 202 is attached on one end to collectors 220-226, whose rear (non-reflective) side is shown. In some embodiments, the shape of collectors 210 is parabolic or another appropriate shape. Support 202 is attached at the other end to thermal structure 214, which includes heat pipe 208, fins 204, four receiver modules (including receiver module 206), and four receivers (including receiver 212). Each receiver in this example is a solar cell and is similarly configured.

Receiver module 206 is the structure to which receiver 212 is attached. In some embodiments, receiver 212 is attached to a cell submount, which is attached to receiver module 206. As shown, receiver module 206 is a ring with a flat surface on one side. The ring may be attached in various ways, including, for example, by mechanically clamping or soldering or adhesive.

In some embodiments, receiver module 206 is not directly attached to heat pipe 208. For example, receiver module 206 may be attached to heat pipe 208 via an adapter. For example, if receiver module 206 is a flat plate, the adapter may have a flat surface on one side for attaching the flat plate and a concave curved surface or a ring on the other side that allows it to be clamped to heat pipe 208. Receiver module 206 may be attached to the adapter in a variety of ways including using screws or an adhesive. In some embodiments, the receiver module and/or adapter are made of copper with an appropriate insulator/dielectric layer. In some embodiments, each collector is 25 cm×25 cm and each solar cell is approximately 1 cm×1 cm. Therefore, the collector concentrates sunlight at a ratio of 25×25 to 1 or 625 to 1.

Concentrated solar radiation on solar cell 212 makes it a heat (or thermal energy) source. Solar concentrating module 200 includes a thermal structure 214 for removing that heat. Thermal structure 214 includes a heat spreader and a heat sink. Heat spreader 208 is a heat pipe in this example, but in other embodiments any appropriate heat spreader may be used. The heat sink includes fins 204. Heat received by receiver 212 is spread along heat spreader 208, which provides a conduction path for moving heat away from the heat source. The heat then radiates off of heat fins 204, which sinks the thermal energy to the environment. In some embodiments, the heat fins are 10 cm×10 cm. Heat spreader 208 may be made of a material that is thermally conductive but electrically insulative or with an appropriate dielectric. Copper has better performance but may be more costly.

Each receiver on module 200 acts as a heat source. Although more heat may be dissipated by the fins nearest to each heat source, a desirable feature of the heat spreader may be that it spreads heat across the heat spreader so that heat dissipation is distributed across the heat fins such that the heat fins farthest from the heat source also dissipate a portion of the heat.

Any appropriate heat transfer mechanism may be used to cool module 200. A variety of combinations of heat spreader(s) and/or heat sink(s) may be used. In various embodiments, the heat spreader may take on various forms. For example, the heat pipe may have a D-shaped extrusion (or D-shaped cross section) as opposed to the cylindrical shape (circular cross section) shown. With a D-shaped extrusion, the solar cell (or cell submount) could potentially be directly attached to the flat portion of the D-shape, in which case the heat spreader and the receiver module are the same. In other embodiments, the heat spreader may be planar. For example, rather than a cylindrical pipe, a flat sheet or plane may be used, an example of which is shown in thermal structure 104 in FIG. 1. Fins may be attached to the front and/or back of the plane.

In various embodiments, the heat sink includes fins, planar fins, and/or shaped, pin fins. Fins may be spaced for natural convection (heat rises off of them) or there may be a fan (forced air convection) used to transfer heat from the fins. In some embodiments, some heat is also radiated off of support 202 and collectors 220-226.

In some embodiments, a hydraulic system is used to remove heat. For example, heat pipe 208 may carry water or another fluid. Heat received by the receiver is absorbed through heat pipe 208 which transfers heat to the fluid. The fluid gets transported down heat pipe 208 to an external pool for cooling. In some embodiments, a phase change is used, in which there is a liquid and the heat causes it to evaporate. It then condenses by the fins. The liquid-vapor transition and condensation are very effective at moving large quantities of heat. For example, a heat pipe, thermosiphon, and/or pool boiling may be used. In some embodiments, mass transport is used, which includes running a fluid through the pipe, not having a phase change, and cooling the fluid externally. The heat fins may provide additional cooling or may be optional in this embodiment. In some embodiments, arrays of module 200 are installed, and heat pipes 208 from multiple modules 200 flow into one or more pipes that transport heated fluid for cooling elsewhere.

As shown in this embodiment, multiple solar cells are sharing the same thermal structure 214 for removing heat from the system, which provides for greater efficiency than if each solar cell has its own thermal structure. There is a smaller parts count, and therefore there are fewer parts that can fail, manufacturing costs are lower, and maintenance is lower.

As shown, the thermal structure is used both as a heat transfer mechanism and as a mechanical structural element, providing rigidity for the structure and a location and position for the cells. By aligning the solar cell using the thermal structure, multiple solar collectors may share the same alignment mechanism, reducing costs and parts count.

Although the shape of the aperture (edge) of the collectors in the examples herein is rectangular or square, in other embodiments, the aperture may take any appropriate shape, such as hexagonal, circular, etc. The techniques described herein apply to any aperture shape. In addition, the techniques described herein describe to other types of collectors, including, for example, Fresnel or refractive systems.

Solar cells and cell assemblies may degrade or be damaged over time, due to age or atmospheric conditions, such as rain, wind, and dust. In addition, it may be desirable to upgrade currently installed solar cells to newer, higher efficiency solar cells. The ability to easily remove parts of module 200 for maintenance, replacement, or upgrade would be desirable. As used herein, removable refers to designed to be attached and detached as a unit.

Typically, a solar cell on a substrate can be bought from a supplier. The substrate is typically then permanently affixed to the system, often with a thermally conductive adhesive, for reasons of good thermal transfer. Disclosed herein is an assembly that can be removed but still has good thermal transfer. One way of doing this is removing the entire thermal assembly, or at least the part that the cell is attached to. Another way of doing this is mounting the cell to a part that can disconnect from the thermal assembly, but that the joint has a low thermal resistance. This can be done with thermal interface materials, mechanical force and clamping on the joint, etc. Details are described more fully below.

In some embodiments, receiver module 206 is removable. Thus, if replacement of solar cell 212 is desired, receiver module 206 may be removed and replaced with a new receiver module having a new solar cell attached to it. In some embodiments, alignment of the new receiver module (so that the solar cell is in the correct position) is maintained using an appropriate alignment technique, such as aligning predrilled holes, marks, clips, or structural elements of the receiver module and/or the heat pipe. For example, the receiver module may be configured such that it locks into place on heat pipe 208 so that the solar cell is in the correct position.

In some embodiments, the solar cell assembly is attached to receiver module 206 in a controlled specialized facility using equipment and workers, but assembly of receiver module 206 onto module 200 may be performed in the field by a relatively unskilled worker with basic tools. The solar cell assembly may be attached to receiver module 206 using soldering, welding, structural pressure, friction from tight fit or clamp, spring clips, adhesive, nuts and bolts, or other fasteners, among others, depending on the thermal conductivity desired and the properties of the material of receiver module 206 and the cell submount.

In some embodiments, thermal structure 214 is removable, including heat pipe 208, heat fins 204, the four receiver modules, and the four solar cells. For example, heat pipe 208 may be detachable at its endpoints from support 202. A new thermal structure 214 may then be installed in its place.

In some embodiments, the entire solar concentrating module 200 is removable from a supporting structure to which support 202 is attached. For example, one or more of modules 200 may be attached to a supporting structure, such as a tracker.

Locating a solar cell at the focus of a parabolic collector leads to the disadvantage of the receiver shading the collector, reducing the effective aperture and efficiency of the collector. In some embodiments, the focal point is moved from an area between the sun and the collector to an area out of the way of the sun's rays during operation.

“During operation” means during the period of the day when the sun is above a minimum elevation design angle, which may exclude a period in the morning and a period in the evening. During operation, the sun's rays always hit the collector at a constant angle because the collector is mounted on a tracker that is configured to follow the sun. However, at low elevation angles (e.g., near sunrise and sunset), depending on the tracker, the tracker may not be designed to follow the sun at low elevation angles. For example, as more fully described below, module 200 may be located on a pivot that allows it to tilt to follow the sun's elevation. However, it may only be able to tilt up to a certain angle, and at or near sunrise and sunset, there may be shadowing by the receiver and/or secondary element on the collector. However, there is less energy in the morning and evening, so this is not a major issue in many systems.

In this example, thermal structure 214 is positioned such that sunlight received by collectors 220-226 is not shadowed by thermal structure 214 during operation. In some embodiments, each collector has a focal point that is not on the line in between the sun and any point on the collector. (non shading)

In addition, fins 204 are attached to heat pipe 208 close to the edges of fins 204 to prevent fins 204 from shadowing collectors 220-226. Fins 204 may extend in any direction away from a direction shadowing collectors 220-226. An advantage of having a non-shadowing receiver or secondary device is that there are fewer limitations to the design of the thermal structure, as long as it does not shadow the collector. By contrast, in a system with a shadowing receiver, any heat spreader and/or heat sink should fit behind the receiver to avoid increasing the shadow size. With a non-shadowing receiver, there is flexibility to also add parts to the thermal structure along the heat spreader, and away from the heat pipe in at least two directions. In addition, secondary elements can be added, such as a secondary reflector, e.g., Cassegrainian, Solfocus. Secondary elements are more fully described below.

In some embodiments, module 200 is configured to track the sun as it moves with time, so that sunlight always hits collector 220 at a constant angle during operation. For example, support 202 may be attached to a structure that allows it to track the location of the sun.

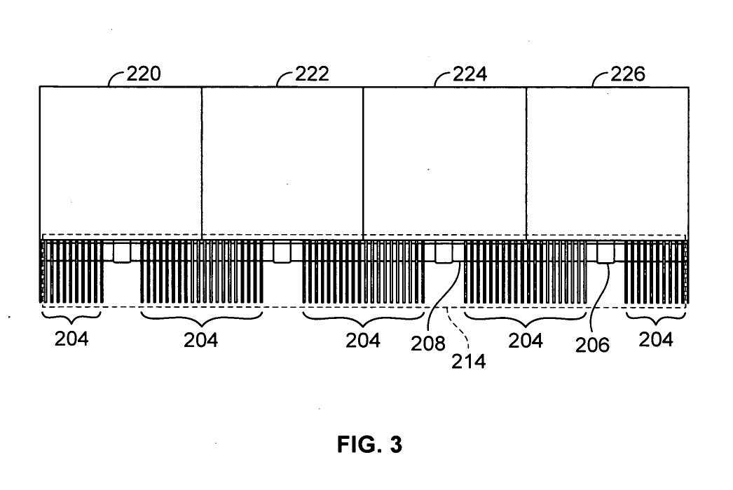

FIG. 3 is a diagram illustrating an embodiment of solar power module 200 from the perspective of the sun. In this example, solar power module 200 is configured to track the sun so that the sun is at the design angle of incidence to the aperture of collectors 220-226. Thermal structure 204, which includes heat pipe 208, fins 204, receiver modules, and receivers, does not shadow collectors 220-226. As shown, the edge of thermal structure 204 lines up with the edges of collectors 220-226. In some embodiments, some tolerance for shadowing on collectors 220-226 is acceptable.

In addition to the receiver, in some embodiments, there may be one or more secondary elements used to modify the distribution of received energy (e.g., sunlight). The distribution includes spectral and/or spatial distribution of energy. Like the receiver, the secondary elements may be placed such that they do not shadow the collector during operation. Methods of mechanical attachment of the receiver and/or secondary element(s) to the solar collectors include thermal adhesives, soldering, welding, structural pressure, friction from tight fit or clamp, spring clips, nuts and bolts, or other fasteners, among others. Examples of secondary elements include a transmissive optic, a reflective optic, a filter, a Cassegrainian secondary element, and a Solfocus secondary element. Some example configurations are described below.

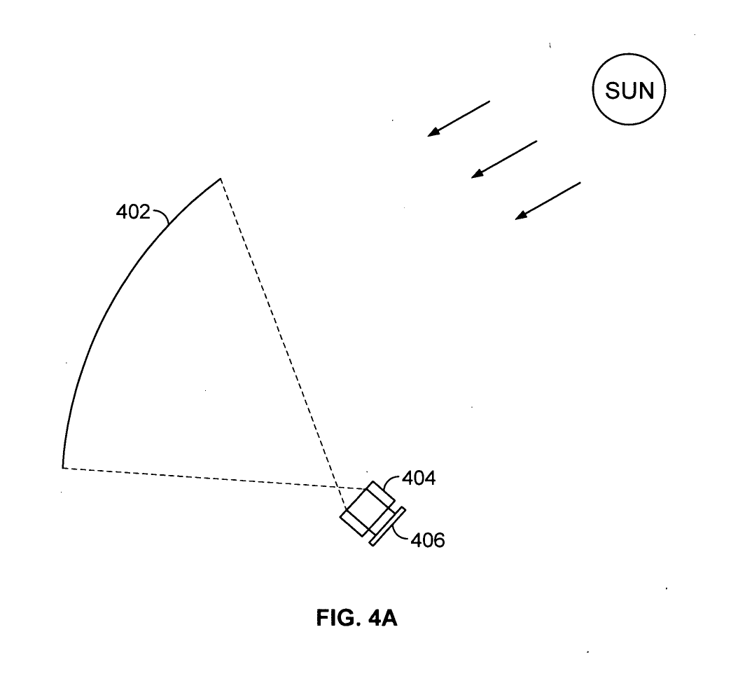

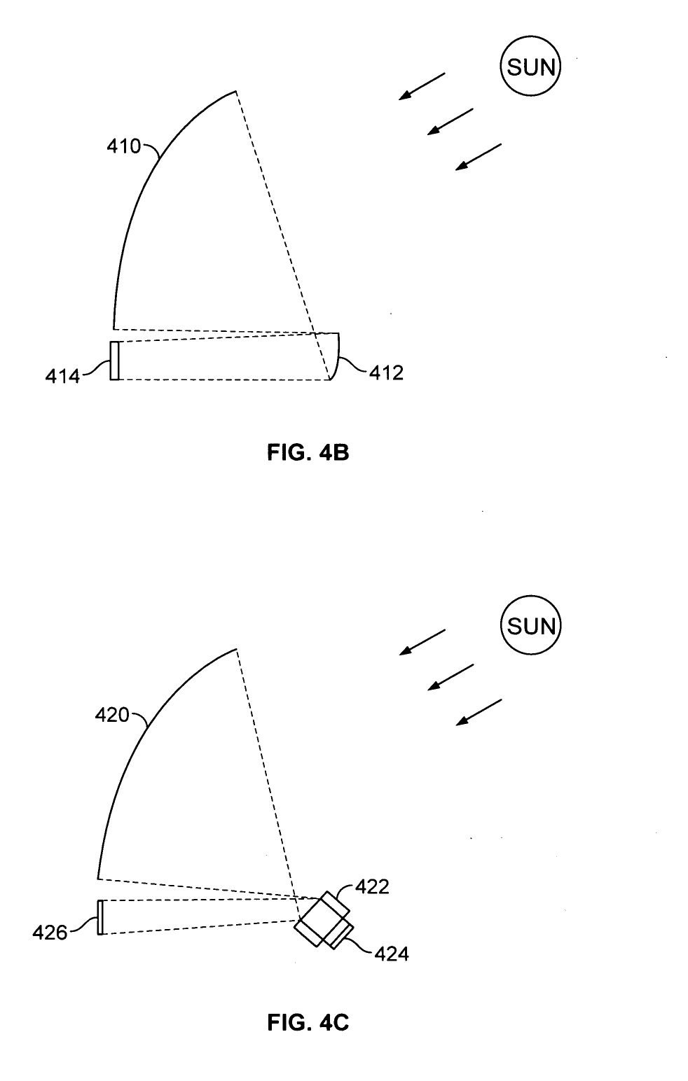

FIG. 4A is a diagram illustrating an embodiment of a concentrating solar power system having a transmissive secondary optic as a secondary element. In the example shown, transmissive secondary optic 404 is placed in front of receiver 406. Sunlight hits collector 402 and is reflected back onto transmissive secondary optic 404. The sunlight travels through transmissive secondary optic 404 before hitting receiver 406. Depending on the type of optic element used, transmissive secondary optic 404 may serve to increase the uniformity of the illumination hitting receiver 406, increase the input or acceptance angle tolerance (the range of angles at which sunlight may hit collector 402 and still reach receiver 406), and/or reduce the angle of incidence of sunlight on the receiver 406. This last characteristic may be useful because in many solar cells, the larger the angle of incidence deviates from normal, the greater the loss due to poor performance of AR (antireflective coating).

FIG. 4B is a diagram illustrating an embodiment of a concentrating solar power system having a reflective secondary element. In the example shown, reflective secondary element 412 is placed at a point of focus opposite collector 410. Receiver 414 is positioned opposite reflective secondary element 412. Sunlight hits collector 410 and is reflected back onto reflective secondary element 412. The sunlight reflects off of secondary element 412 and hits receiver 414. This may be useful because reflective secondary element 412 may be able to bend the incident sunlight in a desirable way so that the reflective secondary element can be placed further from the edge of collector 412 than it would if it were just a receiver. It may also be useful because of the flexibility in locating 414 for mechanical, thermal purposes. In some embodiments, the light can be shaped with the reflective element, and then a refractive light pipe added to help with the acceptance angle at the solar cell. In this case, the refractive light pipe (also referred to as a secondary) can be smaller, as the second reflection puts the light in a more optimal distribution. The more optical surfaces there are, the more opportunities there are to optimize the system. However, each secondary element also introduces a loss, so it may be desirable to not have too many of them.

FIG. 4C is a diagram illustrating an embodiment of a concentrating solar power system having a wavelength splitting secondary element. In the example shown, wavelength splitting secondary element 422 is placed at a point of focus opposite collector 420. Receiver 426 is positioned opposite wavelength splitting secondary element 412. Sunlight hits collector 420 and is reflected back onto wavelength splitting secondary element 422. Wavelength splitting secondary element 422 splits the spectrum of incident sunlight into light having a first spectrum and light having a second spectrum. In some embodiments, light having the first spectrum is reflected to receiver 426 that is responsive to the first spectrum. In some embodiments, light having the second spectrum may be rejected or it may be directed to a second receiver 424 that is responsive to the second spectrum. For example, one solar cell may be responsive to the visible spectrum and one to the infrared spectrum and the wavelength splitter may be used to send visible light to the visible spectrum solar cell and send infrared radiation to the infrared spectrum solar cell. Alternatively, the infrared radiation may be rejected (i.e., remove receiver 424), which helps removes heat from the system.

The one or more secondary elements may be used to modify the distribution of received energy in one or more stages. In some embodiments, each stage has one secondary element, which may each be different. In some embodiments, each stage modifies the distribution of received energy.

Although module 200 is shown to include four solar collectors, in various embodiments, a module may include any number of solar collectors. For example, there may be efficiencies associated with including more solar collectors because all of the solar collectors can share the same thermal structure (heat pipe and fins). In some embodiments, it may be desirable to include fewer solar collectors. For example, module 200 may be adapted to include two solar collectors.

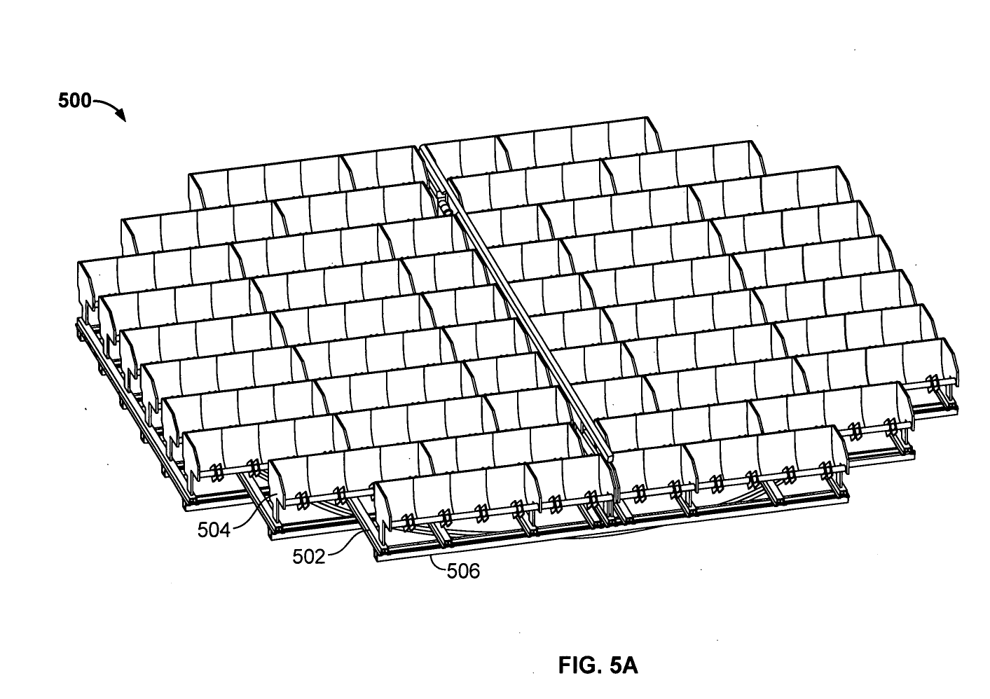

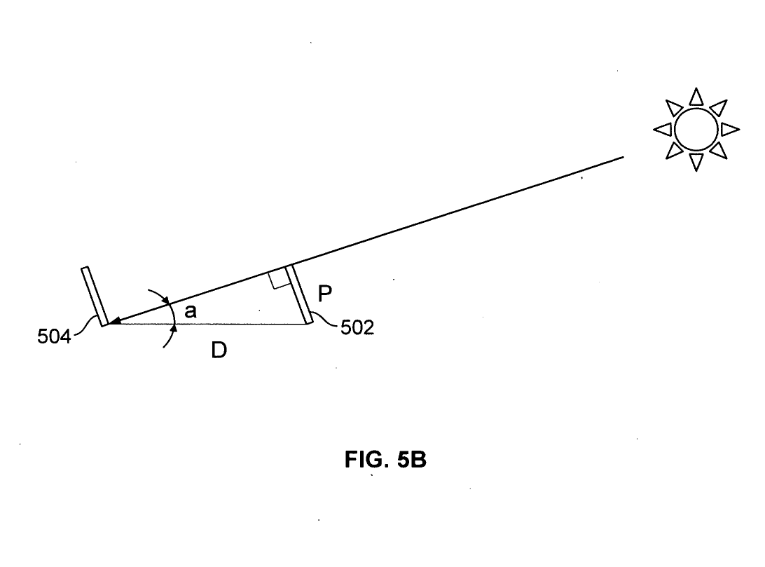

FIG. 5A is a diagram illustrating an embodiment of multiple arrays of solar collectors. In system 500, multiple modules 200 are installed on a supporting structure 506. Each row includes two or more modules 200. For example, row 502 includes four modules 200 installed adjacent to each other: two 4-collector modules 200 and two 2-collector modules 200. Each row is spaced apart from the next row at a spacing such that the sun's rays are not shadowed by the collectors from an adjacent row as long as the sun is above a minimum elevation design angle. The lower the minimum elevation design angle of the sun, the greater the distance between rows to avoid shading. In some embodiments, some shading at low elevation angles is acceptable. For example, at sunrise, the lower elevation of the sun may mean that each array row will be shaded in part by the array row to the East. Near sunset, the lower elevation of the sun may mean that each array row will be shaded in part by the array row to the West. All cells are shaded equally, therefore series losses are minimized. Therefore, the shading is not as bad as some kinds of shading.

FIG. 5B is a diagram illustrating an example of spacing between two rows. In the example shown, rows 502 and 504 are spaced apart by a distance D.

If:

a=minimum elevation design angle

P=mirror (shadowing body) projected distance in sun direction

D=minimum row spacing to eliminate shading

Then the following equation may be used to estimate a minimum spacing between rows:

$$D = \frac{P}{sin α}$$

Thus, by spacing the two rows D apart from each other, if the sun is sufficiently above the horizon (having an elevation angle above the minimum elevation design angle), the two rows will not shade each other. The minimum elevation design angle is a design choice and may vary with different embodiments.

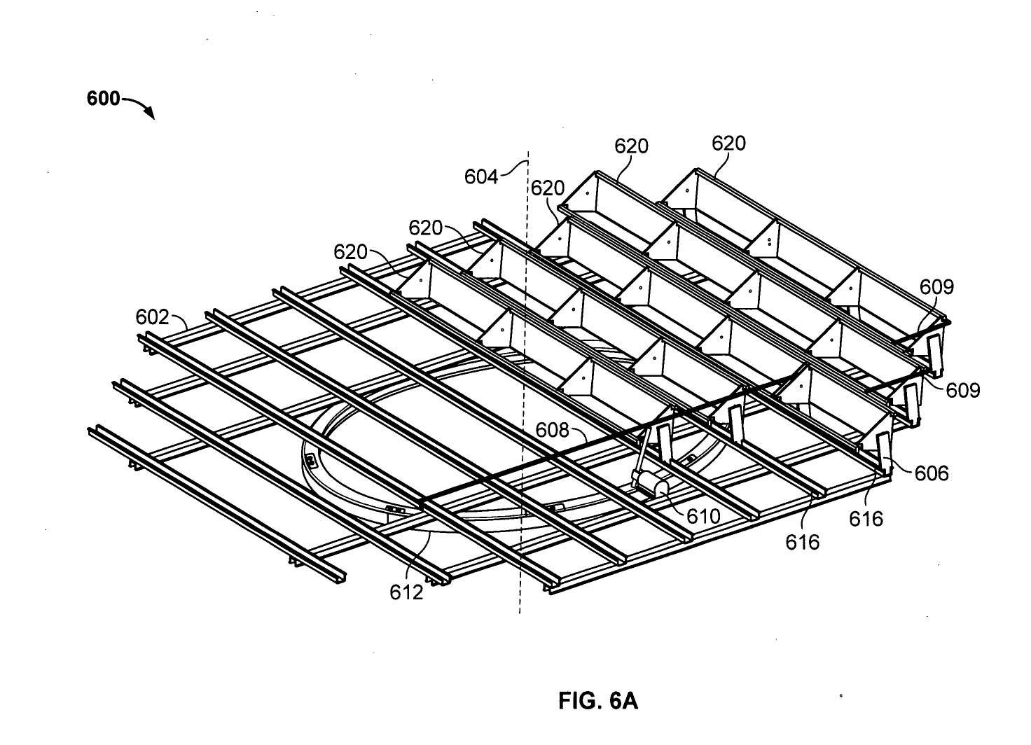

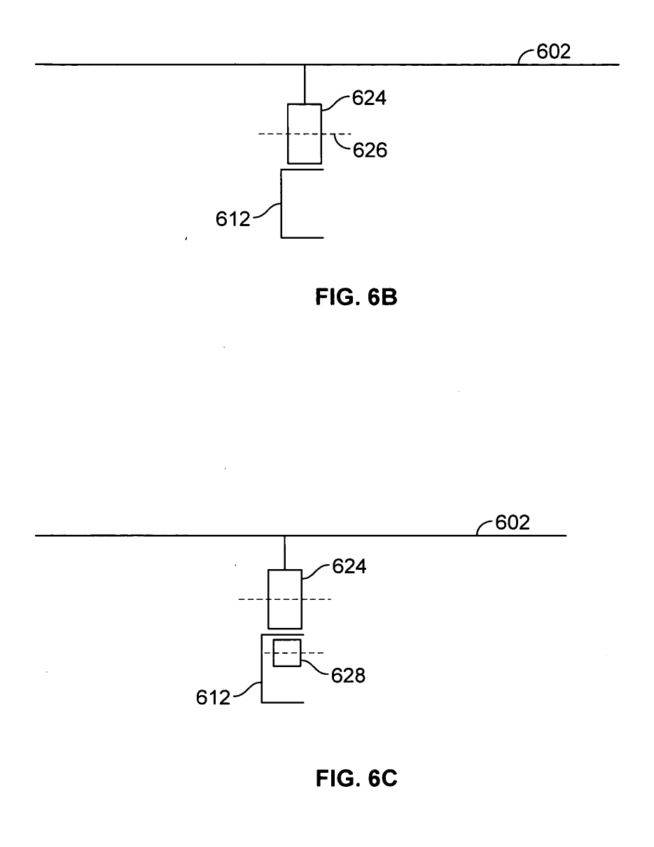

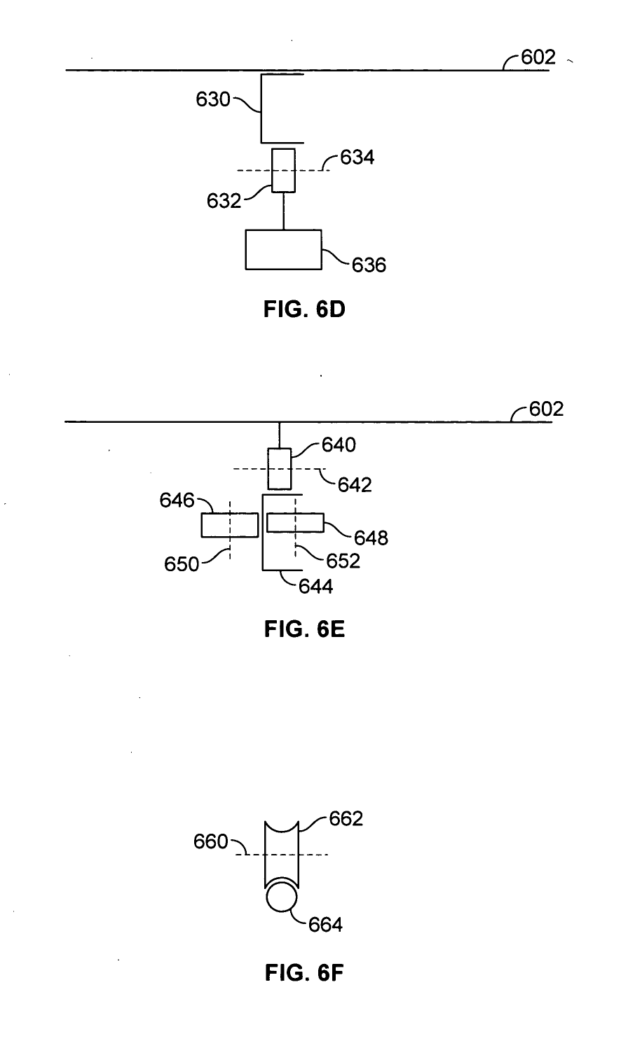

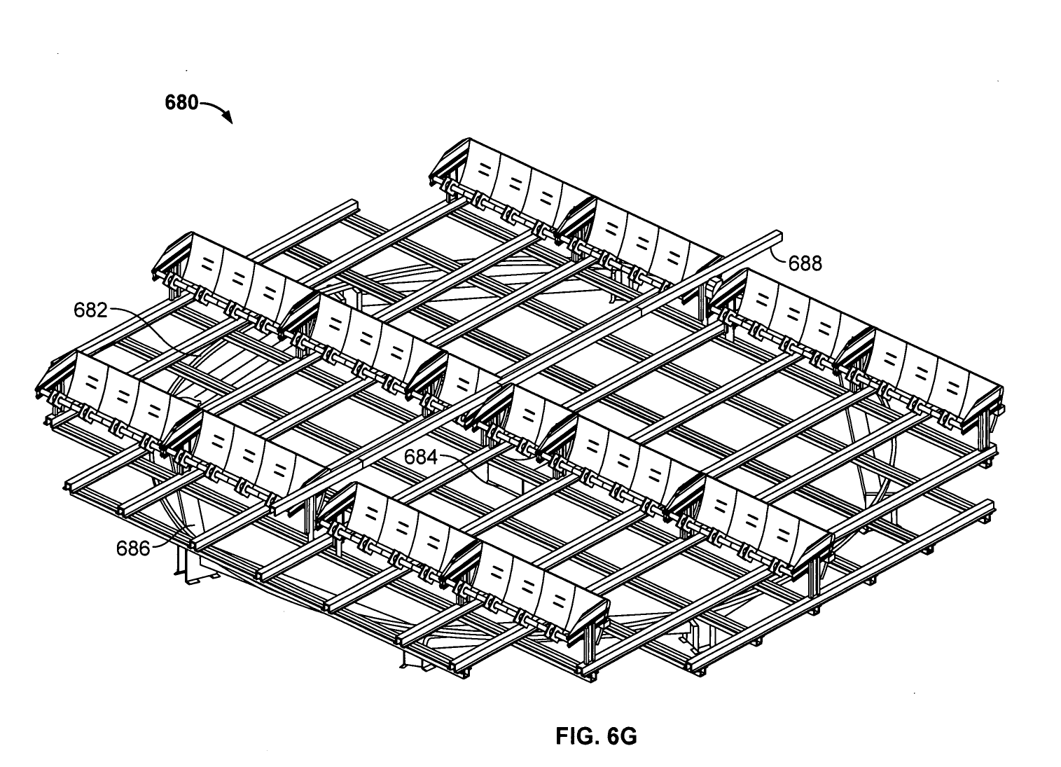

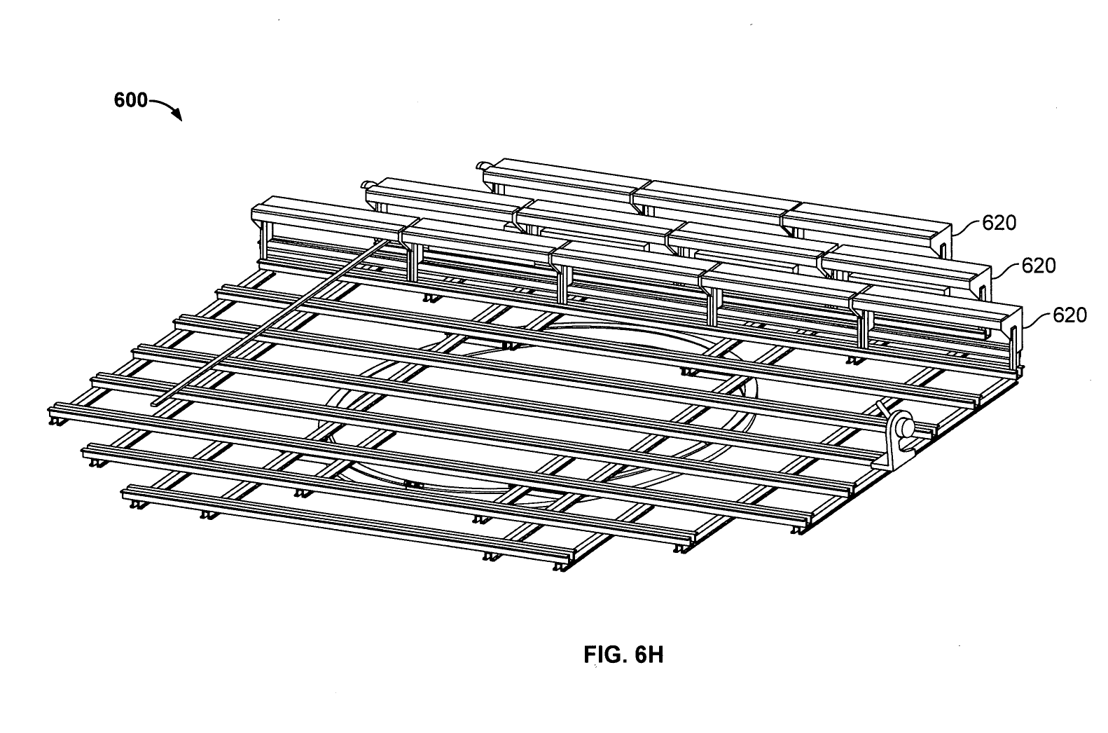

FIG. 6A is a diagram illustrating an embodiment of a tracking platform that may be used to support one or more solar power modules. Concentrated solar radiation collection may include tracking on two axes, one for elevation or elevation in the vertical plane and one for azimuth in the east to west horizontal plane. Tracking may be used to keep the incident radiation at a constant angle (e.g., normal) relative to the solar collector aperture. By installing multiple solar power modules on a single tracking platform, costs are saved. In some embodiments, collectors reach an optimum size at a smaller size than a typical tracker, so a plurality of collectors are placed on one tracker.

Tracking structure 600 enables collectors mounted on row structures 620 to have two degrees of freedom (or two axes)—one around central axis of rotation 604 to adjust the azimuth angle, and a second angular tilt controlled by tie rod 608 to adjust the elevation angle. In other words, an elevation tracking system is mounted on an azimuth tracking system. In some embodiments, more than one track is used. In some embodiments, a central post is used.

Tracking structure 600 is shown to include platform 602 that rotates around a central axis of rotation 604 in a horizontal plane, allowing azimuth angle tracking of the sun. The platform includes row structures 620. Multiple modules 200 may be attached to row structures 620. In various embodiments, various solar power modules may be mounted on tracking structure 600. For example, flat photovoltaic cell panels, a box type receiver (having one or more transmissive elements such as a Fresnel lens), any module that has a planar surface that needs to be oriented towards the sun. Thermal, chemical, or photovoltaic modules may be mounted. Modules that collect other forms of waves, frequency, radiation or light including thermal, photovoltaic, infrared, radio waves, etc., where accurate azimuth and elevation alignment are desirable for their collection, may be mounted.

Each row structure 620 is configured to rotate (tilt) about a pivot to track the elevation angle of the sun and to move into a maintenance position, as more fully described below. Each row structure 620 is attached to tie rod 608. Tie rod 608 is used to control the angle of tilt (elevation angle) of each row structure 620. Tie rod 608 is controlled by motor 610, which is computer controlled. Thus, as the sun moves, motor 610 causes tie rod 608 to tilt each row structure simultaneously to track the elevation angle of the sun. As shown, tie rod 608 is ganged to tie rods 609, i.e., when tie rod 608 is moved in one direction, tie rods 609 move in the same direction because they are connected to each other via rigid row structures. Any number of tie rods may be used for this purpose in other embodiments. The tie rod(s) may be placed in various locations. In some embodiments, tie rod 608 runs down the middle of platform 602. This may be preferable because it causes less twisting on the structure.

Thus, each of row structures 620 shares a common elevation angle adjustment mechanism. Although a tie rod based mechanism is shown in this example, any other mechanism may be used to cause the row structures or solar power modules to adjust in elevation angle. For example, instead of row structures, platform 602 may comprise a frame having vertical supports that are fixed with respect to platform 602. A solar power module may be supported at its ends by the vertical supports. The solar power module may be supported at its ends by pivots so that the solar power module pivots at its ends. The solar power module may include a row of multiple collectors.

In this example, platform 602 rotates about central axis of rotation 604 similarly to a carousel. Although a carousel like platform is shown in this example, in various embodiments, the platform may be any appropriate structure that pivots about a central axis of rotation.

Although five rows of row structures are shown in this example, there may be any number of rows and any number of row structures installed in various embodiments.

Although solar power modules such as module 200 are described in this example as being mounted on platform 602, in various embodiments, any appropriate structure associated with solar power may be mounted on platform 602 and configured to track elevation angle while platform 602 tracks the azimuth angle.

Platform 602 is attached to a number of wheels which ride on circular track 612. Track 612 provides peripheral support for platform 620. One or more wheels is driven by a motor, which is computer controlled (for automatic azimuth angle tracking of the sun). The drive method is friction in this example, or friction of each wheel against track 612. Other drive methods that could be used include using one or more of a cog, chain, or belt. In some embodiments 4 or 8 wheels are used; other embodiments may use a different number of wheels. Track 612 is optionally attached to a base (not shown), which may be used to level the track. The base may be made of concrete or another suitable material. The base may include multiple pieces of concrete to support the tracking structure at various locations.

In this example, the collectors are able to track the sun on a structure that is lower in height (e.g., on the order of 1 meter) than a pole mounted tracker. The lower height enables a greater density of collectors and trackers within a given area as well as less surface area exposed to the elements (e.g., wind). The size of tracking structure 600 can be made larger or smaller as appropriate for the size of the solar power modules and the installation.

In some embodiments, a central post, hub, or pivot is used to keep the wheels from running off the track. For example, a central pivot may be located at the central axis of rotation 604. In some embodiments, central axis of rotation 604 is located at the center of mass of platform 602. The central pivot may be attached to platform 602 to restrict horizontal movement of platform 602. A flanged wheel(s) may be used to prevent slippage off the track, as more fully described below.

Tracking structure 600 is piped or wired appropriately for the type of module used to take the electrical or thermal energy from tracking structure 600 to the point of use. The computer that controls the azimuth and elevation alignment of the modules on tracking structure 600 receives input from a variety of sensors. The computer also has pre-programmed instructions to move the modules to positions appropriate for weather conditions, safety and maintenance. In some embodiments, sensors from a plurality of tracking structures are used to provide input to one or more tracking structures.

The azimuth and elevation position is controlled by a computer that calculates the position of the sun using the date, time, latitude, longitude of the location of tracking structure 600. The computer directs the electric motors controlling azimuth and elevation to move appropriately to align the modules to the calculated position of the sun. The computer receives input from a series of sensors mounted on tracking structure 600, tracking structure components, or not located on tracking structure 600 but nearby in the installation, to fine tune the alignment of the collector modules to collect maximum available energy or to direct the alignment of the modules for safety, weather conditions or maintenance. The sensors include but are not limited to electrical or thermal output of the modules or arrays or platforms, incident solar radiation, temperature of collector modules or their components, relative or absolute mechanical positions components on tracking structure 600, and weather conditions. The computer calculates an ideal azimuth and elevation position adjusted from the calculated position of the sun based on this information. Azimuth and elevation alignment positions of the collector modules are preprogrammed or calculated for night, rain, wind, hail, fog, snow, dust storm, cleaning, safety and maintenance for the present invention. The computer receives digital or analog information and sends digital or analog instructions the motors, sensors, and other devices that are part of tracking structure 600 or installation of tracking structures via wires or a wireless network. The controlling computer may be connected via the internet for control of tracking structure 600 and monitoring tracking structure 600 or installations of tracking structures. In some embodiments, the altitude and elevation of a tracking structure is optimized for power output and/or feedback control, independent of the sun's location.

In some embodiments, the parts of tracking structure 600 are designed, manufactured and pre-assembled where possible for convenient shipping and fast installation at the project site. The parts may be marked and designated for serial assembly. Predrilled materials, studs for module attachment, and other forms of fasteners may be used for fast and accurate assembly. The materials for constructing tracking structure 600 may be selected as appropriate. Steel, aluminum or other metals or plastic or other materials may be used. In addition, fastening methods such as welding, bolting or other methods may be used as appropriate for the size, weight and construction of tracking structure 600.

A variety of drive mechanisms may be used to rotate platform 602, as described below. In some embodiments, more than one drive mechanism is used per tracking structure. The drive mechanisms can be positioned along any point of the platform where mechanically appropriate and may face towards the central axis of rotation or away from it. For example, four drive mechanisms may be evenly spaced apart on track 612. In some embodiments, at least two drive mechanisms are placed opposite each other on track 602.

FIG. 6B is a diagram illustrating an embodiment of a drive mechanism used to rotate platform 602. In this example, platform 602 is attached to load bearing wheel 624. Wheel 624 has horizontal axis of rotation 626. Wheel 624 rests on track 612 and is driven by a motor. Thus, both the platform 602 and the wheels 624 and 628 rotate around the central axis of rotation 604.

FIG. 6C is a diagram illustrating an embodiment of a drive mechanism used to rotate platform 602. FIG. 6C is a variation of FIG. 6B in which there is a lower wheel 628 located in the cavity of track 612 that is used to pinch the top wheel 624 to track 612 and therefore prevent slippage. Either the upper wheel 624 or the lower wheel 624 or both may be driven by a motor. Alternatively, in place of lower wheel 628, a weight may be used to prevent slippage off the track. Like FIG. 6B, both the platform 602 and the wheels rotate around the central axis of rotation 604.

FIG. 6D is a diagram illustrating an embodiment of a drive mechanism used to rotate platform 602. In this example, platform 602 is attached to circular track 630. Track 630 rests on a load bearing wheel 632. Wheel 632 has horizontal axis of rotation 634. Wheel 632 is attached to a base 636. Therefore, both platform 602 and track 630 rotate around the central axis of rotation 604. Wheel 632 is driven by a motor.

FIG. 6E is a diagram illustrating an embodiment of a drive mechanism used to rotate platform 602. In this example, platform 602 is attached to a load bearing wheel 640. Wheel 640 rests on circular track 644. An inner lower wheel 648 is located in the cavity of track 644. Inner lower wheel 648 has a vertical axis of rotation 652, and rests against the inner wall of track 644. Inner lower wheel 648 may be driven by a motor, causing upper wheel 640 to rotate, which causes platform 602 to rotate around the central axis of rotation 604. Optionally, an outer lower wheel 646 may be located on the opposite side of the track from the inner lower wheel. The outer lower wheel has a vertical axis of rotation 650 and rests against the outer wall of track 644. Outer lower wheel 646 is used to pinch inner lower wheel 648 to track 644.

In some embodiments, the wheel and/or track is shaped in a manner that helps prevent slippage of the wheel off the track. FIG. 6F is a diagram illustrating an embodiment of a wheel and a track that are shaped to help prevent slippage of the wheel off the track. A vertical cross section of the wheel 662 resting on the track 664 is shown. Wheel 662 has a horizontal axis of rotation 660. The cross section of track 664 is curved. The surface of wheel 662 that contacts track 664 is shaped to conform to the shape of the track. In other words, the cross section of wheel 662 shows a curved bottom and top that “wrap” around the top portion of track 664. In some embodiments, a flanged wheel(s) is used. In some embodiments, this is similar to a train wheel.

FIG. 6G is a diagram illustrating an alternative embodiment of a tracking platform that may be used to support one or more solar power modules. In this diagram, the solar power modules are shown.

In this embodiment, tracking structure 680 is shown to include three rows of solar power modules. A combination of 2-unit modules and 4-unit modules are installed. There is a large ring 682 around the outside. There is also a central bearing 684 for supporting the structure (so it doesn't sag in the middle). In some embodiments, there are 2 or more rings used for support. Ring 682 rotates around central bearing 684, the wheels (not shown) are on the ground and are stationary. Octagonal structure 686 is on the ground and spaces the wheels out (wheels at each intersection). One of the sets of wheels is driven. The elevation drive 688 goes down the middle. In some embodiments, a linkage is used to connect the rows to elevation drive 688. In some embodiments, tracking structure 680 sits on concrete blocks (not shown).

FIG. 6H is a diagram illustrating an embodiment of a tracking structure in which all the row structures are in a maintenance state. In this example, system 600 is shown with three row structures (instead of five row structures shown in FIG. 6A), where the row structures are positioned in a maintenance position. Specifically, each row structure 620 is rotated so that when a solar power module (such as module 200) is attached to the row, the aperture of the collector faces a maintenance direction. In some embodiments, the maintenance direction is substantially facing the ground (i.e., is upside down), protecting the receiver from the elements. As previously described, each row structure 620 is rotated to the maintenance position via tie rods 608 and 609 using motor 610. In some embodiments, the maintenance position is a position that is outside of the operating range of a module attached to row structure 620. As used herein, the operating range of a module is a range of elevation angles such that when the module is oriented at an elevation angle within the operating range, the module is intended to be operational. The operating range of a module is a design choice and may vary with different embodiments.

In some embodiments, there is more than one maintenance position for various purposes, such as service access. Each maintenance position may be associated with orienting a row structure at a different elevation angle. For example, there may be a maintenance position for wind loading, sun avoidance, reducing dust collection, and for a wash sequence. For purposes of explanation, the following examples assume one maintenance position. However, in other embodiments, multiple maintenance positions may be used for different purposes. For example, one type of maintenance position may be the stowed position, which may be used for stowing at night when the system is not operational. In some embodiments, the stowed position is an upside down position.

Having a maintenance position may be useful for protecting the collectors and/or receiver from inclement weather, such as hail, rain, and particles (e.g., sand), as well as for cleaning and mechanical maintenance. The maintenance position may be used at night when the collector is not operational. The maintenance position may also be used if there is a fault condition. For example, if an error is detected, then affected modules may be placed in the maintenance position to prevent damage. In addition, the maintenance position decreases wind load on the structure, so during high wind conditions, the maintenance position may be used. For maintenance reasons, the maintenance position may be used to purposely prevent power generation from one or more receivers.

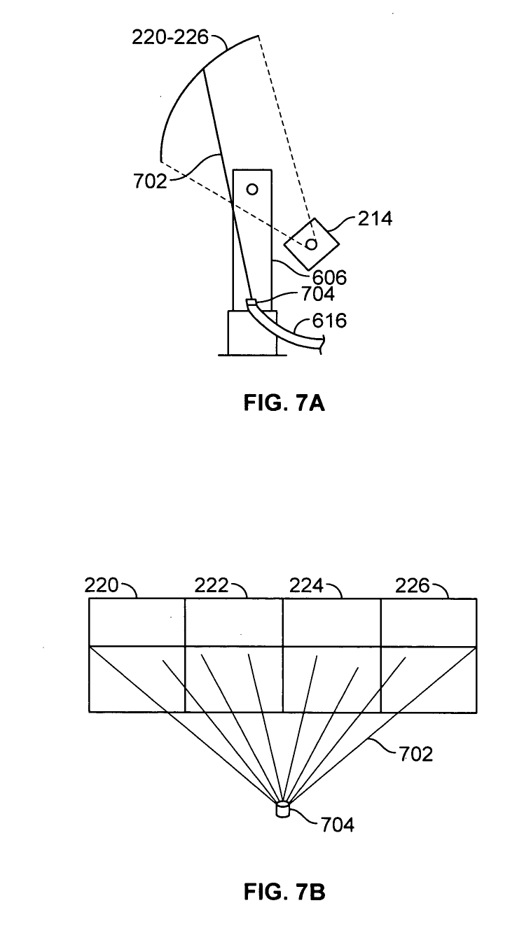

FIG. 7A is a diagram illustrating an embodiment of a configuration used to wash one or more collectors. In some embodiments, it would be desirable to have an automated washing mechanism for a collector, whose performance degrades when it is dirty. A collector can become dirty due to atmospheric conditions, such as rain, hail, dust particles, etc.

In this example, a side view of module 200 installed on a tracking structure 600 is shown. As shown, collectors 220-226 and thermal structure 214 are located above support 606. In some embodiments, support 202 (shown in FIG. 2) is attached to support 606 (also shown in FIG. 6A). A pipe or tube 616 carrying water or another cleaning agent is positioned near the base of support 606 and a stationary fan nozzle 704 is directed towards collectors 220-226. As previously described, collectors 220-226 are configured to rotate using tie rod 608 as controlled by motor 610. In some embodiments, while the collectors are rotating, a horizontal, flat jet of water 702 is sprayed towards the collectors to clean the collectors. In some embodiments, water 702 is low volume and high pressure. In some embodiments, the nozzle may be placed in such a way that it also cleans the receiver and/or any secondary elements (located on thermal structure 214).

FIG. 7B is a diagram illustrating an embodiment of a configuration used to wash one or more collectors when facing the aperture of the collectors. Flat jet of water 702 is directed at a horizontal line across collectors 220-226. Collectors 220-226 rotate over the jet of water 702, causing the entire surface of the apertures to be sprayed. Any appropriate cleaning agent may be used. For example, a surfactant may be added to the water. The water may be deionized or filtered to reduce deposits. In addition, a hydrophobic coating may be applied to the collectors to reduce streaking. In some embodiments, nozzle 704 outputs pulses of spraying. In some embodiments, nozzle 704 outputs a steady stream.

In some embodiments, washing is performed while transitioning to the maintenance position in the evening. If there are many collectors that need to be washed, there may not be enough water pressure to handle washing all the collectors at once. In some embodiments, washing is performed on different subsets of collectors at various times at night, i.e., a first subset transitions from the maintenance position to an operational position while being sprayed by the jet of water 702, and then returns to the maintenance position. Optionally, the jet of water 702 continues to spray during the return to the maintenance position. In some embodiments, the nozzle is configured (e.g., programmed) to emit water only when the spray would hit the collector.

As shown in FIG. 6A, pipe 616 runs down the entire row of collectors in each row (pipe 616 is labeled for two rows). One fan nozzle may be used for one or multiple collectors. One valve may be used for an entire tracking structure or multiple tracking structures. In some embodiments, the nozzle is actuated by water pressure, similar to a pop up lawn sprinkler.

In some embodiments, rather than the nozzle being stationary and the collectors moving over the nozzle, the nozzle moves over the collectors while the collectors remain stationary. For example, the nozzle may be configured to move in response to water pressure, similar to a moving lawn sprinkler. In some embodiments, both the nozzle and collectors may move during washing.

Although this washing mechanism has been described with respect to the example concentrating solar power modules 200 and 600, it may be used with any type of solar application, including flat panel solar cells, solar troughs, box type receivers; thermal, chemical, or photovoltaic modules having reflective and/or transmissive elements; and modules that collect other forms of waves, frequency, radiation or light including thermal, photovoltaic, infrared, radio waves, etc.

The maintenance position mechanism and/or washing mechanism may be computer controlled so they occur at pre-programmed times or are triggered by certain events, e.g., detected by sensors. For example, if a dust storm is detected, the modules may be automatically placed in the maintenance position. After a dust storm, the modules may be automatically washed.

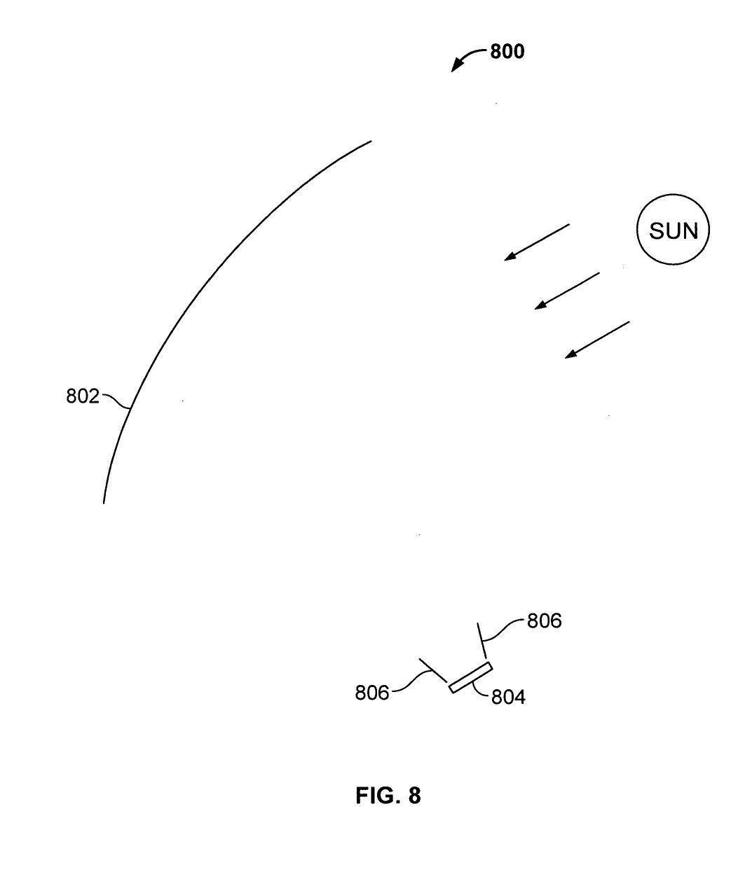

FIG. 8 is a diagram illustrating an embodiment of a concentrating solar power system having a reflective secondary optic as a secondary element. In system 800, reflective secondary optic 806 is placed in front of receiver 804. Solar energy or sunlight hits collector 802 and is reflected back onto reflective secondary optic 806 and/or receiver 804. Solar energy received at reflective secondary optic 806 is reflected such that at least a portion of the solar energy hits receiver 804. Secondary optic 806 increases the input or acceptance angle tolerance (the range of angles at which sunlight may hit collector 802 and still reach receiver 804), and/or reduce the angle of incidence of sunlight on the receiver 804. This last characteristic may be useful because in many solar cells, the larger the angle of incidence deviates from normal, the greater the loss due to poor performance of AR (antireflective coating).

Reflective secondary optic 806 has the advantage of offering zero transmission loss when collector 802 is sufficiently aligned. In other words, any sunlight reflected from collector 802 that directly hits receiver 804 (without reflecting off secondary optic 806) has zero transmission loss, in contrast to if a transmissive secondary optic were placed over receiver 804 as shown in FIG. 4A.

The geometry of secondary optic 806 may vary in various embodiments, based on a number of factors, such as the shape of receiver 804 and/or the shape of the active area of receiver 804, where the active area is the portion of receiver 804 at which sunlight received at that portion can be converted to electricity. Many solar cells are rectangular and as such, it may be desirable for secondary optic 806 to have a rectangular cross section. It may also desirable for the reflective surfaces of secondary optic 806 to have sharp mating edges, as more fully discussed below.

In some embodiments, receiver 804 and/or reflective secondary optic 806 are mounted in a manner that avoids shading of collector 802 during operation. In some embodiments, at least one of receiver 804 and secondary optic 806 is located off-axis to solar collector 802.

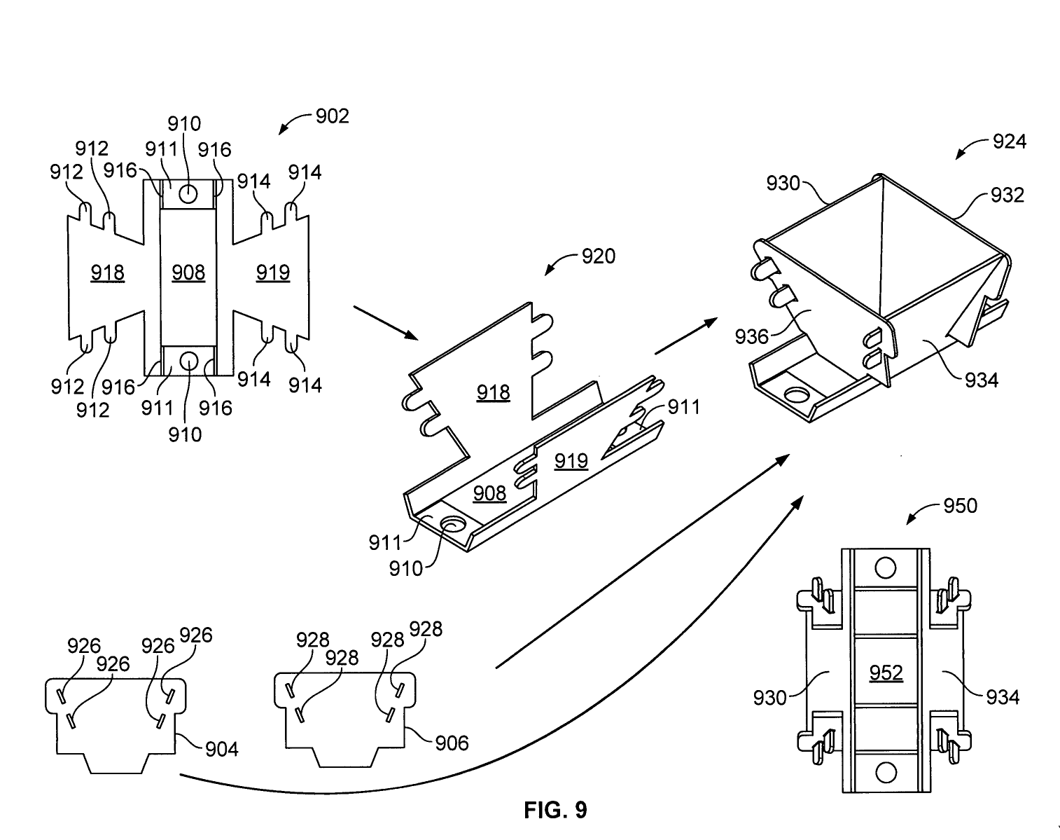

FIG. 9 is a diagram illustrating various views of an embodiment of a reflective secondary optic. Pieces 902, 904, and 906 are each cut or formed from a flat sheet into the shapes shown. Pieces 902, 904, and 906 are used to form or construct reflective secondary optic 924. Secondary optic 924 is an example of secondary optic 806. (FIG. 8 shows a side view or cross sectional view of secondary optic 806.)

Piece 902 includes eight tabs total, including four tabs 912 extending out of left side 918 and four tabs 914 extending out of right side 919. Piece 902 includes cut out regions 908 and 910. In other words, regions 908 and 910 are cut out of the sheet.

Piece 904 includes four tab slots 926 and piece 906 includes four tab slots 928. Tab slots 926 and 928 are sized such that tabs 912 and 914 can be inserted inside the tab slots.

Piece 920 is piece 902 with left side 918 and right side 919 folded or bent upwards along crease or bend lines 916 towards the interior of the piece as shown.

Reflective secondary optic 924 includes piece 920 with side pieces 904 and 906 placed on either side of piece 920. Side pieces 904 and 906 are attached to piece 920 by inserting tabs 912 and 914 on piece 920 into the tab slots on pieces 904 and 906.

In this embodiment, reflective secondary optic 924 comprises 4 facets or walls—facet 930, facet 932, facet 934, and facet 936. Facets 930 and 934 are formed from sides 918 and 919. Facets 932 and 936 are formed from pieces 904 and 906. The facets form a truncated pyramid shaped structure. In FIG. 8, secondary optic 806 shows the two sides of a cross section of the truncated pyramid structure.

Reflective secondary optic 924 is hollow, comprising the four facets, an entry aperture, and an exit aperture. In this drawing, the entry aperture is shown at the top of the structure and the exit aperture is located at the bottom, as shown by bottom view 950 of secondary optic 924. In bottom view 950, exit aperture 952 is shown in the center. In this embodiment, the apertures are both rectangular or square in shape. In some embodiments, the apertures could have other shapes. In this embodiment, secondary optic 924 comprises three pieces—piece 902, piece 904, and piece 906. Pieces 902, 904, and 906 could be cut from the same sheet or two or three flat sheets. A variety of materials could be used for the sheets, as more fully described below.

The interior of secondary optic 924 is reflective. Solar energy is received at the entry aperture at the top (in this drawing), reflected from the interior surface and the reflected energy is output from the exit aperture at the bottom (in this drawing). A receiver (e.g., a solar cell) may be placed at or near the exit aperture such that it receives at least a portion of the energy output from the exit aperture.

The entry aperture is larger than the exit aperture. This allows for a greater range of incident angles for solar energy incident on the entry aperture such that the solar energy still hits the receiver. When solar energy enters the entry aperture and exits the exit aperture without being reflected against the interior surface of secondary optic 924, then there is 0% loss associated with reflective secondary optic 924. This compares with about 5% loss when using a refractive or transmissive secondary optic. In other words, if light passes right through the hollow of secondary optic 924 without hitting the interior surface, then there is no loss. This would mean that system 800 is positioned such that collector 802 is causing the light received at secondary optic 924 to be “nominally aligned” with receiver 804. Aligned means that system 800 is positioned such that 90% of the light incident on the surface of collector 802 is received at receiver 804. When system 800 is positioned such that 100% of the light received at receiver 804 is reflected off secondary optic 924, then there is about 10% loss due to secondary optic 924. This compares with about 5% loss when using a refractive or transmissive secondary optic. When system 800 is positioned such that 50% of the light received at receiver 804 is reflected off secondary optic 924, the loss is comparable to the loss when using a refractive or transmissive secondary optic.

In this embodiment, the interior of secondary optic 924 does not include bends in the reflective interior surface. There are no bends in the sheets at the edges where the facets meet. Instead the edges of the sheets butt against each other. This may be desirable because it provides for sharp mating edges (where the facets meet or “mate” at their edges), which lowers the non-reflective surface of secondary optic 924. In other words, if instead facet 930 and facet 932 were formed from a single sheet and bent at the edge where they meet, that bend has a radius, which reduces the overall reflective surface area of the interior of secondary optic 924. For example, there might be cracks or damage in the coating due to the stress in the vicinity of the bend. This may cause reliability issues because moisture or other debris may get in the cracks and can cause failure of the material. An example of this embodiment is described more fully below.

In some embodiments, cut out regions or holes 910 are used to mechanically mount or attach the structure to a supporting structure, such as to receiver module 206 of FIG. 2. For example holes 910 may be sized such that a screw can be inserted through holes 910. Also, if needed, base 911 (or the portion of the sheet from which 910 is cut out) may be sized to provide a defined spacing between the edge of base 911 and another structure.

The interior of secondary optic 924 is reflective. Some materials that may be used in secondary optic 924 include metal, such as aluminum or anodized aluminum. The interior may be coated with silver to increase reflectivity. Dielectric layers may be applied on top of the silver layers to provide environmental protection for the silver. Any coating/layer may be applied to parts 902, 904, and 906 (before assembly of secondary optic 924, while the parts are flat). Any coating/layer may be applied to the sheet(s) from which parts 902, 904, and 906 are cut. Various materials that may be used in various embodiments are more fully described below.

Thus, secondary optic 924 provides a variety of benefits, including: reduced loss of reflective surface area at the bends or joints (mating edges); lower cost of manufacture compared to transmissive secondary optics (low material and fabrication costs, on the order of 20-30 cents); and a capability to pre-coat reflective surfaces prior to forming, thus reducing overall cost.

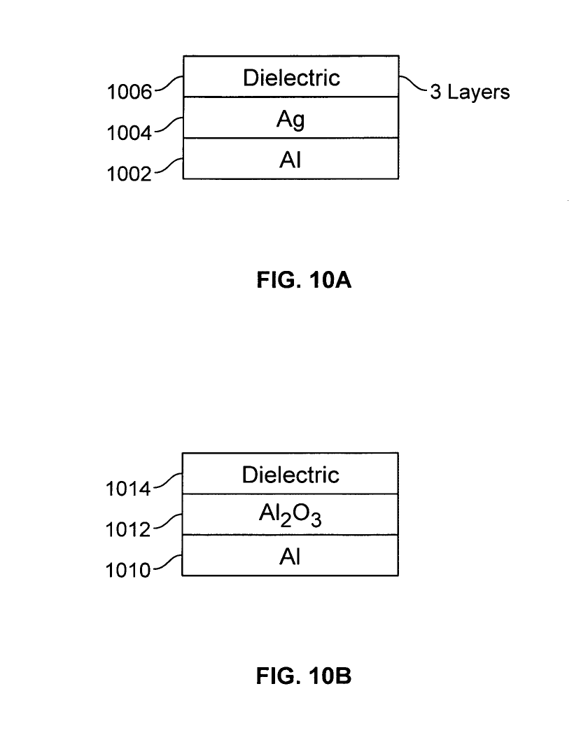

FIG. 10A is a diagram illustrating an embodiment of a cross section of a sheet from which the facets of secondary optic 924 are formed. In some embodiments, a sheet of aluminum 1002 is covered with a layer of silver 1004 to provide reflectivity. Silver layer 1004 is covered with one or more layers of dielectric material 1006 to protect silver layer 1004 and/or provide desirable reflectivity properties. For example, three layers of dielectric material are used in some embodiments. In some embodiments, the silver layer ranges from 10 nanometers to 100 nanometers while the dielectric layer is 0.5 to 10 nanometers thick. Different thicknesses might apply depending on the materials chosen.

FIG. 10B is a diagram illustrating another embodiment of a cross section of a sheet from which the facets of secondary optic 924 are formed. This is an example of Solarphire manufactured by PPG Industries. In some embodiments, a sheet of aluminum 1010 is covered with a layer of ceramic 1012 (Al₂O₃), which is covered with one or more layers of dielectric material 1014. Various materials may be used for ceramic 1012 in various embodiments. In some embodiments, the thicknesses of each layer are in the range of 0.5 to 100 nanometers.

Other materials that might be used in secondary optic 924 include glass with a coating on the front and/or back surface of the glass; aluminum polished such that it provides sufficient reflectivity, without the use of silver, which may be advantageous because aluminum lasts longer than silver in an outdoor environment; various reflective films applied to aluminum or other materials, such as plastic, glass, or steel; and float glass. In the case of plastic, plastic could be injection molded, or sheets of plastic could be used. The interior of the plastic secondary optic could be coated by means of evaporation or thin film metallization with aluminum or silver, or a reflective film could be applied to it.

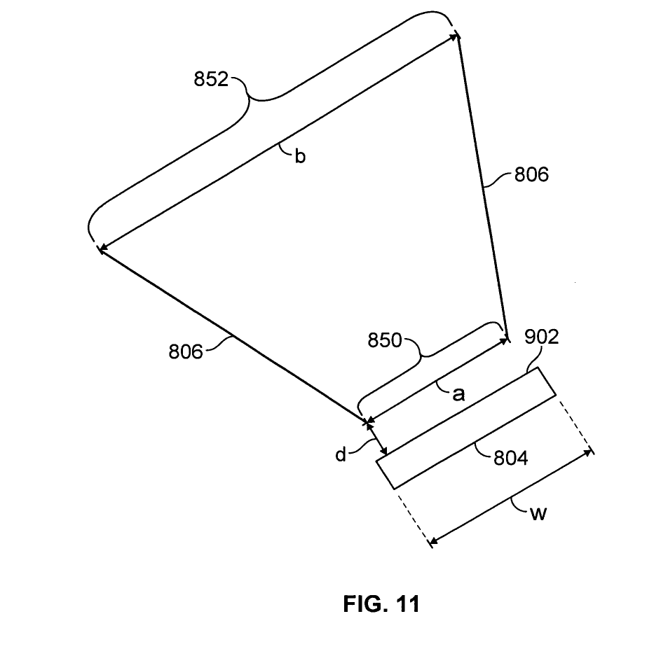

FIG. 11 is a diagram illustrating an embodiment of a secondary optic. This figure shows a close up of secondary optic 806 and receiver 804 in FIG. 8. In this example, secondary optic 806 has the truncated pyramid shape of secondary optic 924. As shown, secondary optic 806 includes an entry aperture 852 with size b (e.g., the length of a side of the rectangular shaped opening) and an exit aperture 850 with size a (e.g., the length of a side of the rectangular shaped opening). Receiver 804 has an active area 902. There is a gap between exit aperture 850 and active area 902. The distance between exit aperture 850 and active area 902 is d. The size of active area 902 is w (e.g., the length of a side if the active area is rectangular in shape). The reason for the gap is that in some embodiments, there is a coating or encapsulant on top of active area 902 in order to provide dielectric protection for receiver 804. In some embodiments, the coating or encapsulant is optically clear, but may take up some distance d.

In some embodiments, w>a because of the distance d or gap between exit aperture 850 and active area 902. Having the gap means that light exiting from exit aperture 850 can escape from the gap if the angle at which light exits exit aperture 850 is high enough. By sizing active area 902 to be larger than the size of exit aperture 850, at least some of that light can be captured and prevented from escaping.

Given the distance d and a maximum angle α (at which light exits exit aperture 850) at which light is desired to be captured, it is possible to derive a formula for a as a function of d and a for various exit aperture shapes.

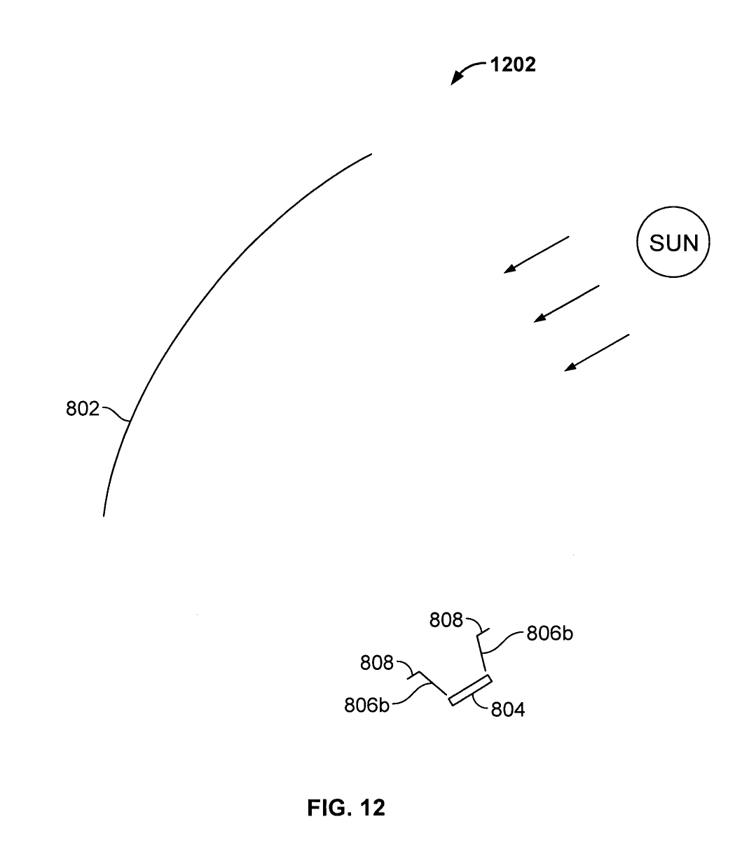

FIG. 12 is a diagram illustrating an embodiment of a concentrating solar power system having a reflective secondary optic that has a shield. In FIG. 8, secondary optic 806 can be viewed as a “catcher” of sunlight, increasing the input angle tolerance of light directed at the receiver. However, any light reflected back from collector 802 that is not “caught” by secondary optic 806 could hit sensitive components of receiver 804 or other sensitive components in the vicinity of receiver 804, potentially causing heat damage.

In system 1202, reflective secondary optic 806b includes a shield 808. Shield 808 extends at an angle from the entry aperture of secondary optic 806b such that light reflected back from collector 802 that hits the vicinity outside the entry aperture hits shield 808. In this way, shield 808 functions to protect sensitive components of receiver 804 or other sensitive components in the vicinity of receiver 804 on the opposite side of shield 808 from which light hits. In some embodiments, at least a portion of shield 808 is part of the same sheet as one or more facets or sides of secondary optic 806b. For example, in FIG. 9, part 902 could have sides 918 and 919 extend further out, and parts 904 could extend further out towards the top. These extensions would then be folded down along the edges shown in FIG. 9 to form a shield. In various embodiments, the extensions could have a variety of shapes and sizes.

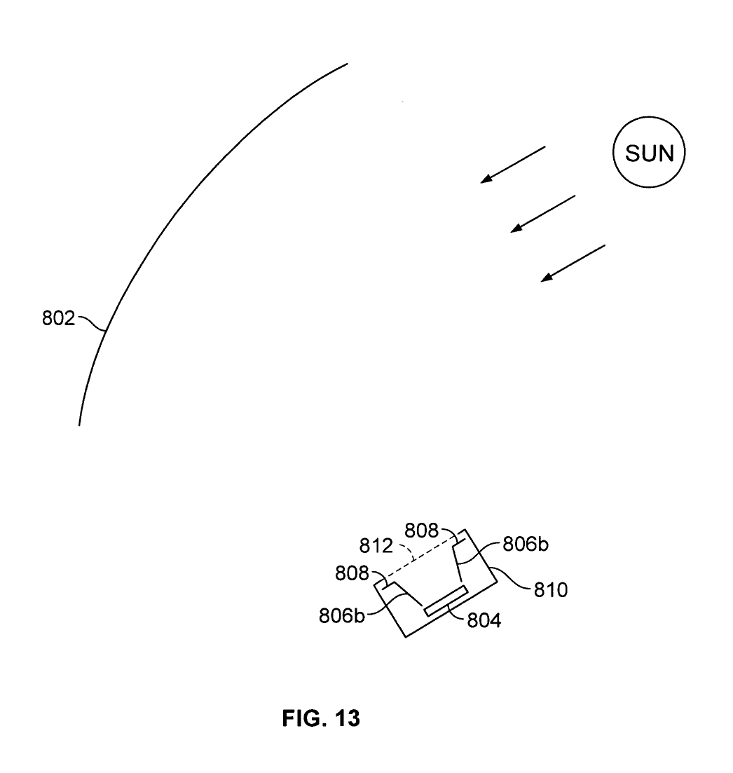

FIG. 13 is a diagram illustrating an embodiment of a concentrating solar power system having a reflective secondary optic that is enclosed in a protective box. In this embodiment, secondary optic 806b and receiver 804 are enclosed in a protective box 810. In some embodiments, protective box 810 is sealed such that water, dirt, etc., cannot damage secondary optic 806b and/or receiver 804. For example, if silver is used in secondary optic 806b, because silver does not respond well to water, such protection might be desirable. Box 810 includes a window 812 so that light can still reach secondary optic 806b and receiver 804. In some embodiments, box 810 is made of metal so that it can handle the high heat that is associated with concentrated sunlight. In some embodiments, window 812 is made of glass. The glass could perform a protective function and/or provide an optical function, such as filtering out undesired wavelengths of light. In some embodiments, an antireflective (AR) coating is applied to the window to help prevent loss of light going through the window. In some embodiments, a coating that filters out infrared (IR) light and/or ultraviolet (UV) light can be applied. IR light causes extra heating and lowers performance. UV light causes the receiver to degrade faster. In some cases, UV light is the largest reliability concern for materials inside the receiver. Box 810 can take a variety of shapes besides a rectangular box.

In some embodiments, window 812 extends across the entire side of box 810. In some embodiments, window 812 extends across a portion of a side of box 810. In this case, the portion that is metal may serve a protective/shielding function and eliminate or reduce the need for shield 808.

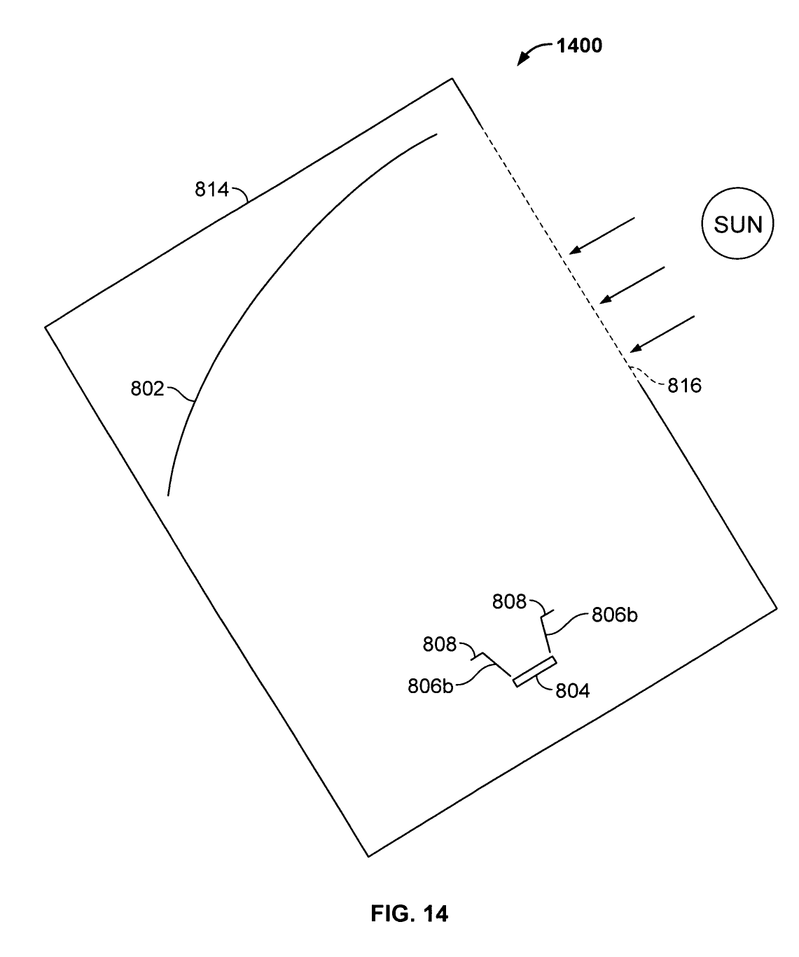

FIG. 14 is a diagram illustrating an embodiment of a concentrating solar power system having a reflective secondary optic and a collector, both are which are enclosed in a protective box. System 1400 illustrates another example of a way to protect secondary optic 806b and/or receiver 804 from the environment. In this example, collector 802, secondary optic 806b, and receiver 804 are enclosed in a box 814. Box 814 includes a window 816 through which sunlight can pass. In some embodiments, box 814 is made of metal and window 816 is made of glass. Window 816 may have one or more coatings, as described above with respect to window 812. Box 814 can take a variety of shapes besides a rectangular box.

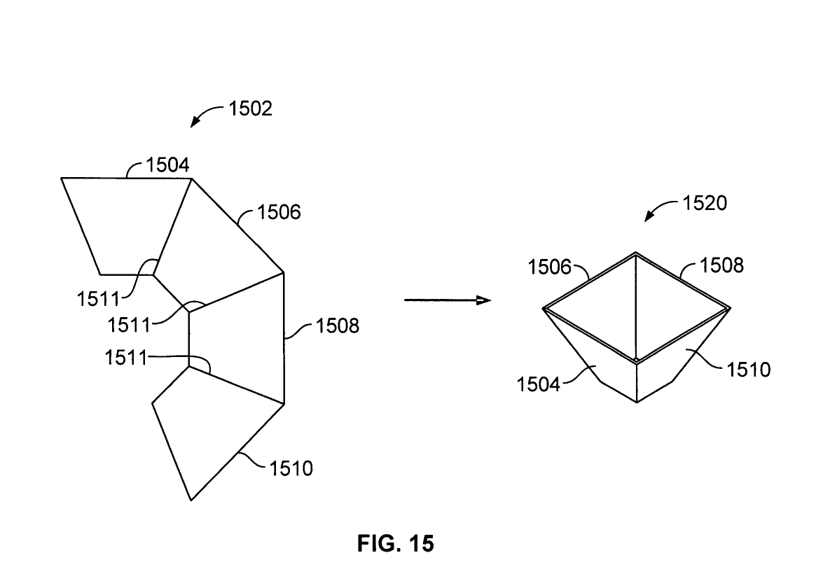

FIG. 15 is a diagram illustrating various views of another embodiment of a reflective secondary optic. Piece 1502 is cut from a flat sheet into the shape shown. Piece 1502 includes four facets—facet 1504, facet 1506, facet 1508, and facet 1510. Piece 1502 is used to construct or form reflective secondary optic 1520. Secondary optic 1520 is an example of secondary optic 806.

Piece 1520 is piece 1502 with facets 1504-1510 folded along crease or bend lines 1511 into a truncated pyramid shape as shown. Reflective secondary optic 1520 is hollow, comprising the four facets, an entry aperture, and an exit aperture. In this drawing, the entry aperture is shown at the top of the structure and the exit aperture (not visible in this drawing) is located at the bottom. In this embodiment, the apertures are both rectangular or square in shape. In some embodiments, the apertures could have other shapes. In this embodiment, piece 920 comprises a single piece—piece 1502, which is cut from a single flat sheet. A variety of materials could be used for the sheets, as previously described.

The interior of secondary optic 1520 is reflective. Solar energy is received at the entry aperture, reflected from the interior surface and the reflected energy is output from the exit aperture. A receiver (e.g., a solar cell) may be placed at or near the exit aperture such that it receives the energy output from the exit aperture.

Secondary optic 1520 is an alternative embodiment to secondary optic 924 and has similar functional properties to secondary optic 924. However, the interior of secondary optic 1520 includes bends in the reflective interior surface. This may be undesirable in some embodiments because it lowers the non-reflective surface of secondary optic 924.

The interior of secondary optic 1520 is reflective. Materials, layers, and/or coatings that may be used in secondary optic 1520 are similar to those that may be used in secondary optic 924.

Thus, secondary optic 1520 provides a variety of benefits, including lower cost of manufacture compared to transmissive secondary optics, and a capability to pre-coat reflective surfaces prior to forming, thus reducing overall cost.

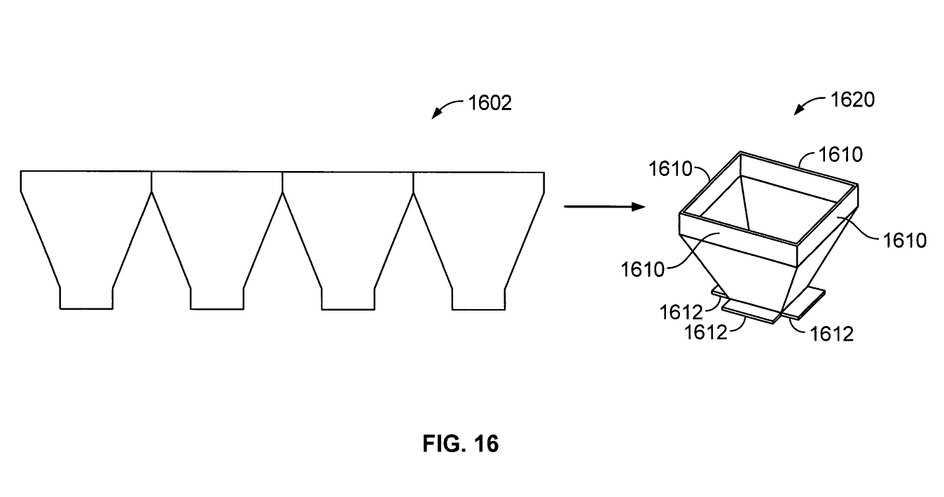

FIG. 16 is a diagram illustrating various views of another embodiment of a reflective secondary optic. Piece 1602 is cut from a flat sheet into the shape shown. Piece 1602 is used to construct or form reflective secondary optic 1620. Secondary optic 1620 is an example of secondary optic 806.

Piece 1620 is piece 1602 folded into a truncated pyramid shape as shown. Reflective secondary optic 1620 is hollow, comprising four facets, an entry aperture, and an exit aperture. In this drawing, the entry aperture is shown at the top of the structure and the exit aperture (not visible in this drawing) is located at the bottom. In this embodiment, the apertures are both rectangular or square in shape. In some embodiments, the apertures could have other shapes. In this embodiment, piece 1620 comprises a single piece—piece 1602, which is cut from a single flat sheet. A variety of materials could be used for the sheets, as previously described.

The interior of secondary optic 1620 is reflective. Solar energy is received at the entry aperture, reflected from the interior surface and the reflected energy is output from the exit aperture. A receiver (e.g., a solar cell) may be placed at or near the exit aperture such that it receives the energy output from the exit aperture.

Secondary optic 1620 is an alternative embodiment to secondary optic 924 and has similar functional properties to secondary optic 924. The interior of secondary optic 1620 includes bends on the “cuff” portion 1610 of secondary optic 1620. Cuff 1610 of secondary optic 1620 may or may not be reflective on its interior in various embodiments. In some embodiments, the function of cuff 1610 is to provide an attachment between the four facets and cuff 1610 does not serve a reflective function. In some cases secondary optic 1620 may be desirable over secondary optic 1520 because there are no bends in the reflective portion of the interior of secondary optic 1620 and/or because the bends are shorter in secondary optic 1620 than in secondary optic 1520.

At least a portion of the interior of secondary optic 1620 is reflective. Materials, layers, and/or coatings that may be used in secondary optic 1620 are similar to those that may be used in secondary optic 924.

Base 1612 may be used to mechanically mount or attach the structure to a supporting structure, such as to receiver module 206 of FIG. 2. Also, if needed, base 1612 may be sized to provide a defined spacing between an edge of base 1612 and another structure. Base 1612 may extend out further and/or have a variety of shapes in various embodiments.

Thus, secondary optic 1620 provides a variety of benefits, including: lower cost of manufacture compared to transmissive secondary optics; a capability to pre-coat reflective surfaces prior to forming, thus reducing overall cost; and reduced loss of reflective surface area at the bends or joints (mating edges).

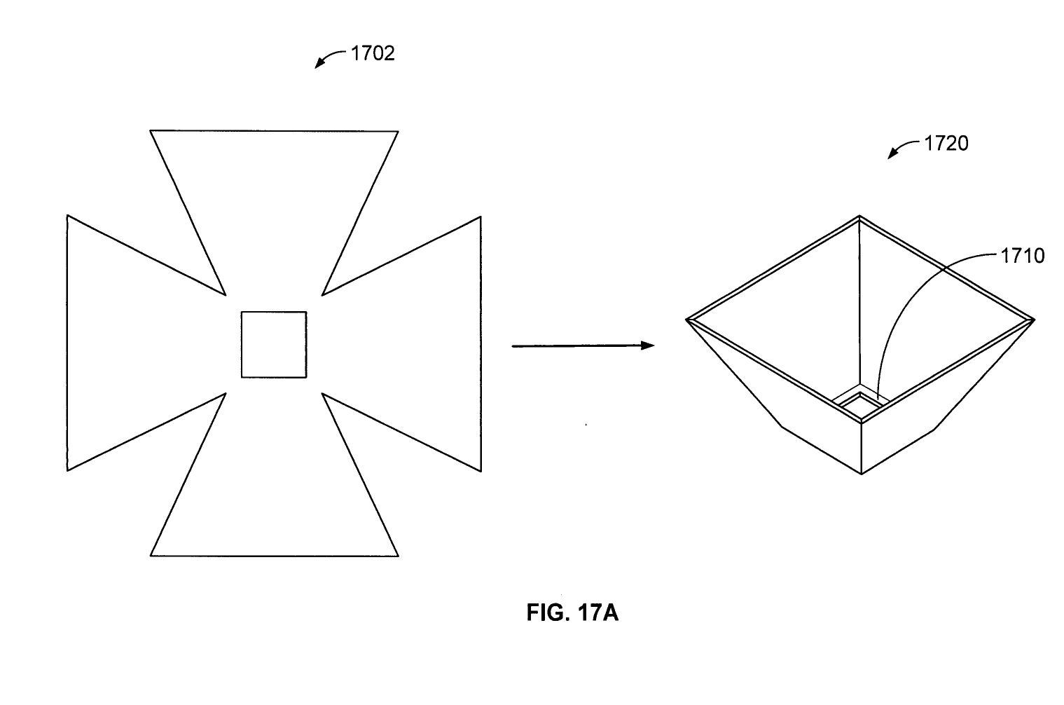

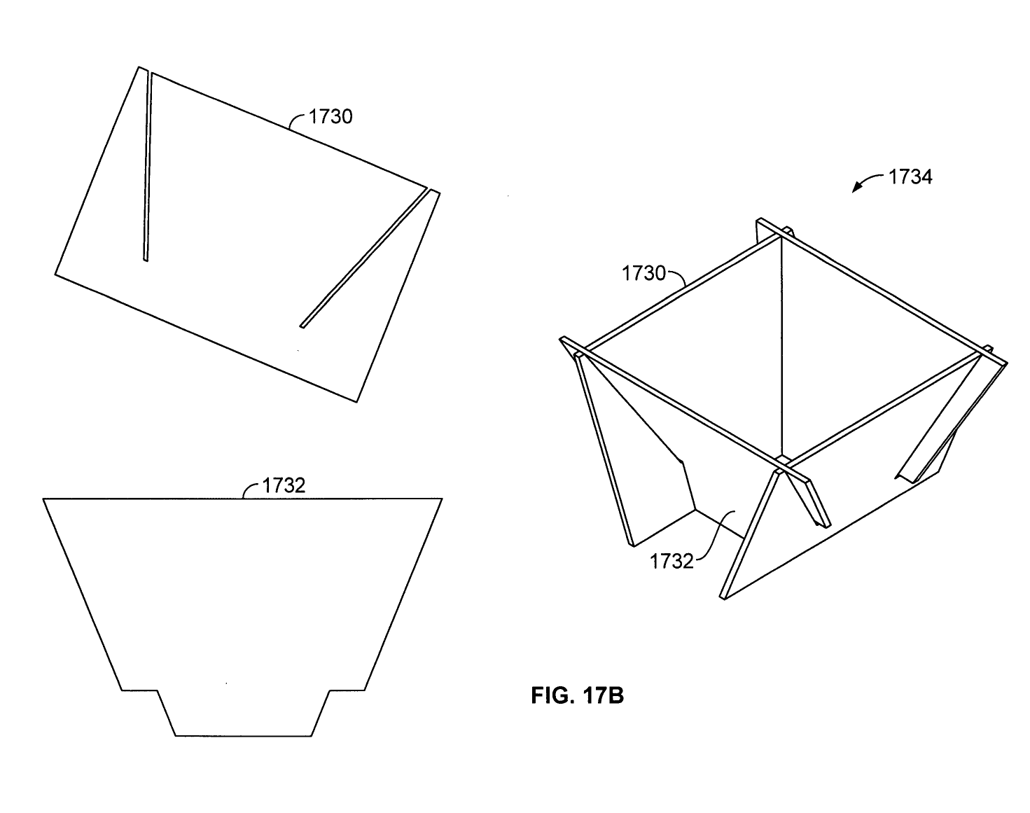

FIG. 17A is a diagram illustrating various views of another embodiment of a reflective secondary optic. Piece 1702 is cut from a flat sheet into the shape shown. Piece 1702 is used to construct or form reflective secondary optic 1720. Secondary optic 1720 is an example of secondary optic 806.

Piece 1720 is piece 1702 folded into a truncated pyramid shape as shown. Each facet of piece 1702 is folded or bent upwards to form lip 1710, as shown in piece 1720. The four facets are connected along lip 1710 around the exit aperture. Reflective secondary optic 1720 is hollow, comprising four facets, a lip 1710, an entry aperture, and an exit aperture. In this drawing, the entry aperture is shown at the top of the structure and the exit aperture is located at the bottom. In this embodiment, the apertures are both rectangular or square in shape. In some embodiments, the apertures could have other shapes. In this embodiment, piece 1720 comprises a single piece—piece 1702, which is cut from a single flat sheet. A variety of materials could be used for the sheets, as previously described.

The interior of secondary optic 1720 is reflective. Solar energy is received at the entry aperture, reflected from the interior surface and the reflected energy is output from the exit aperture. A receiver (e.g., a solar cell) may be placed at or near the exit aperture such that it receives the energy output from the exit aperture.

Secondary optic 1720 is an alternative embodiment to secondary optic 924 and has similar functional properties to secondary optic 924. The interior of secondary optic 1720 includes bends on the “lip” portion 1710 in the interior of secondary optic 1720. Lip 1710 of secondary optic 1720 may or may not be reflective on its interior in various embodiments. In some embodiments, the function of lip 1710 is to provide an attachment between the four facets and lip 1710 does not serve a reflective function. In some cases secondary optic 1720 may be desirable over secondary optic 1520 because there are no bends in the reflective portion of the interior of secondary optic 1720.

At least a portion of the interior of secondary optic 1720 is reflective. Materials, layers, and/or coatings that may be used in secondary optic 1720 are similar to those that may be used in secondary optic 924.

Thus, secondary optic 1720 provides a variety of benefits, including: lower cost of manufacture compared to transmissive secondary optics; a capability to pre-coat reflective surfaces prior to forming, thus reducing overall cost; and reduced loss of reflective surface area at the bends or joints (mating edges).

FIG. 17B is a diagram illustrating various views of another embodiment of a reflective secondary optic. Two each of pieces 1730 and 1732 are cut from a flat sheet into the shapes shown. Two of pieces 1730 and two of pieces 1732 are used to construct or form reflective secondary optic 1734. Secondary optic 1734 is an example of secondary optic 806.

Piece 1732 slides into one of the slots in piece 1730 on one side and into one of the slots of another piece 1730 on the other side. The second piece 1732 slides into the remaining slots, as shown in secondary optic 1734.

Reflective secondary optic 1734 is hollow, comprising four facets, an entry aperture, and an exit aperture. In this drawing, the entry aperture is shown at the top of the structure and the exit aperture is located at the bottom. In this embodiment, the apertures are both rectangular or square in shape. In some embodiments, the apertures could have other shapes. A variety of materials could be used for the sheets, as previously described.

The interior of secondary optic 1720 is reflective. Solar energy is received at the entry aperture, reflected from the interior surface and the reflected energy is output from the exit aperture. A receiver (e.g., a solar cell) may be placed at or near the exit aperture such that it receives the energy output from the exit aperture.

Secondary optic 1734 is an alternative embodiment to secondary optic 924 and has similar functional properties to secondary optic 924. In some cases secondary optic 1734 may be desirable over secondary optic 1520 because there are no bends in the reflective portion of the interior of secondary optic 1734.

At least a portion of the interior of secondary optic 1734 is reflective. Materials, layers, and/or coatings that may be used in secondary optic 1734 are similar to those that may be used in secondary optic 924.

Thus, secondary optic 1720 provides a variety of benefits, including: lower cost of manufacture compared to transmissive secondary optics; a capability to pre-coat reflective surfaces prior to forming, thus reducing overall cost; and reduced loss of reflective surface area at the bends or joints (mating edges).

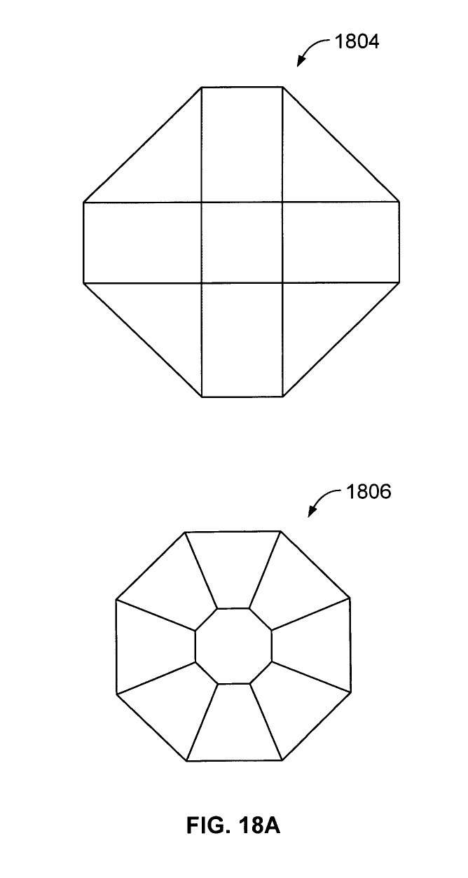

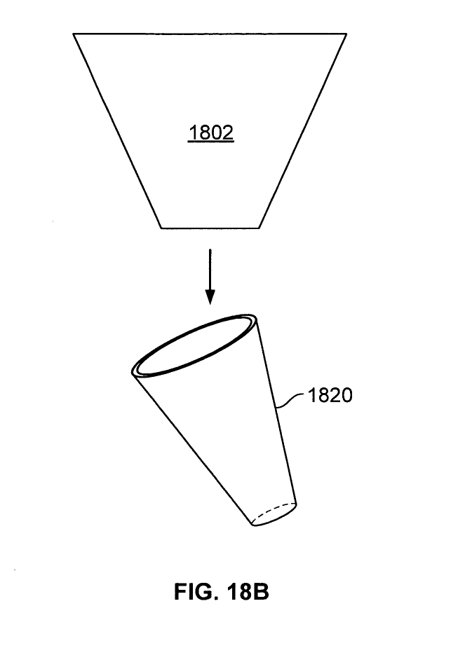

A secondary optic may take a variety of shapes besides a four faceted, truncated pyramid shape. For example, eight facets may be desirable in some cases. FIG. 18A illustrates embodiments of an eight faceted reflective secondary optic.

Secondary optics 1804 and 1806 are shown from the perspective of looking straight down the center from the side of the exit aperture, normal to the exit aperture.

Secondary optic 1804 includes four rectangular facets and four triangular facets. In this embodiment, the entry aperture is octagonal and the exit aperture is rectangular or square. This may be advantageous over a four faceted secondary optic due to increased collection efficiency from the four triangular facets that are not present in the four faceted secondary optic.

Secondary optic 1806 includes eight identical wedge shaped facets. In this embodiment, both the entry aperture and the exit aperture are octagonal. If the active area of the receiver is circular, this embodiment may be desirable because an octagon may be used to approximate a circle.

FIG. 18B is a diagram illustrating various views of another embodiment of a reflective secondary optic. Piece 1802 is cut from a flat sheet into the shape shown. Piece 1802 is used to construct or form reflective secondary optic 1820. Secondary optic 1820 is an example of secondary optic 806.

Secondary optic 1820 is piece 1802 curved into a truncated conical shape as shown. The cross section of secondary optic 1820 is a circle or ellipse. Reflective secondary optic 1820 is hollow, comprising an entry aperture and an exit aperture. In this drawing, the entry aperture is shown at the top of the structure and the exit aperture is located at the bottom. In this embodiment, the apertures are both circular or elliptical in shape. In this embodiment, piece 1820 comprises a single piece—piece 1802, which is cut from a single flat sheet. A variety of materials could be used for the sheets, as previously described.

The interior of secondary optic 1820 is reflective. Solar energy is received at the entry aperture, reflected from the interior surface and the reflected energy is output from the exit aperture. A receiver (e.g., a solar cell) may be placed at or near the exit aperture such that it receives the energy output from the exit aperture. If the active area of the receiver is circular or elliptical, this embodiment may be desirable.

Secondary optic 1820 is an alternative embodiment to secondary optic 924 and has similar functional properties to secondary optic 924. The interior of secondary optic 1820 does not include bends, which may be desirable. At least a portion of the interior of secondary optic 1820 is reflective. Materials, layers, and/or coatings that may be used in secondary optic 1820 are similar to those that may be used in secondary optic 924.

Thus, secondary optic 1820 provides a variety of benefits, including: lower cost of manufacture compared to transmissive secondary optics; a capability to pre-coat reflective surfaces prior to forming, thus reducing overall cost; and reduced loss of reflective surface area at the bends or joints (mating edges).

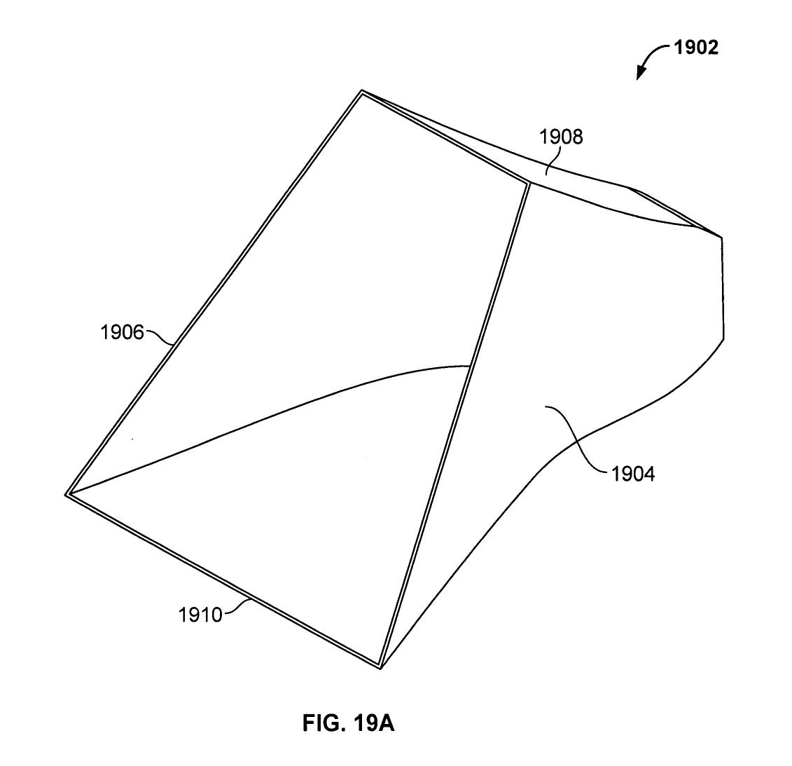

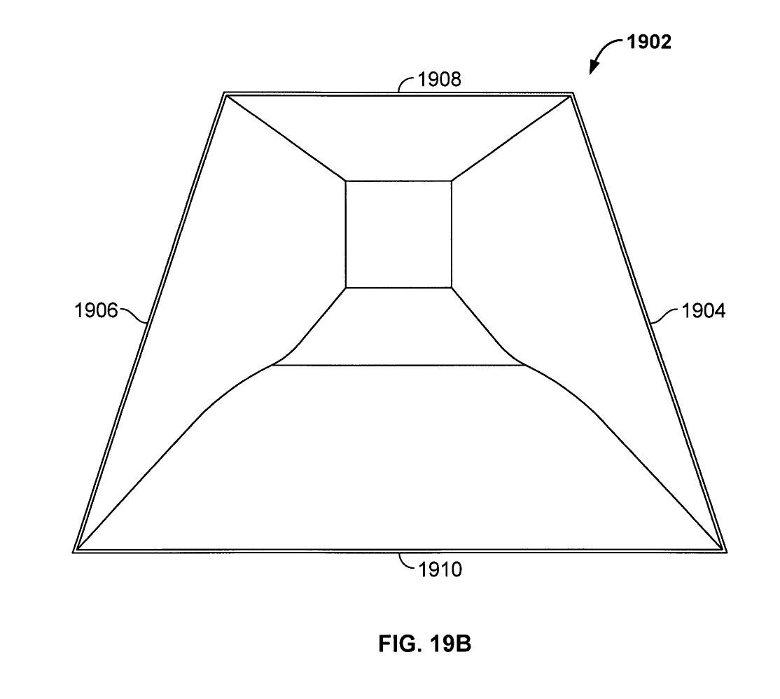

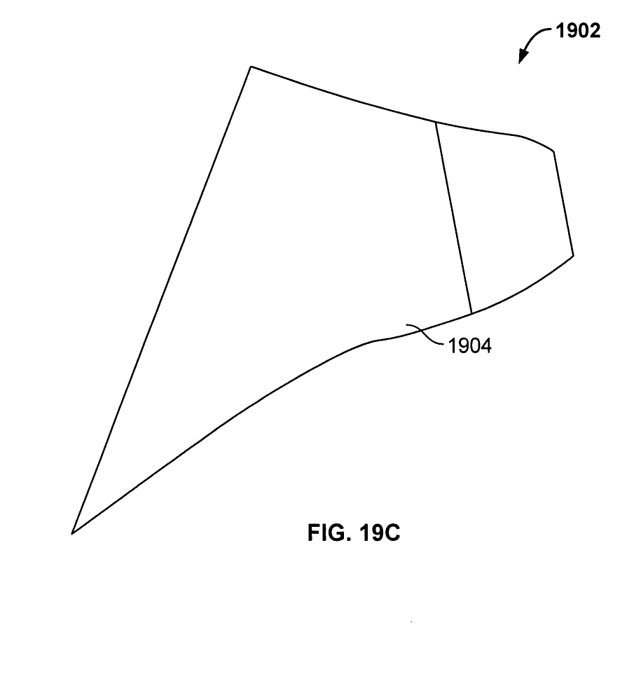

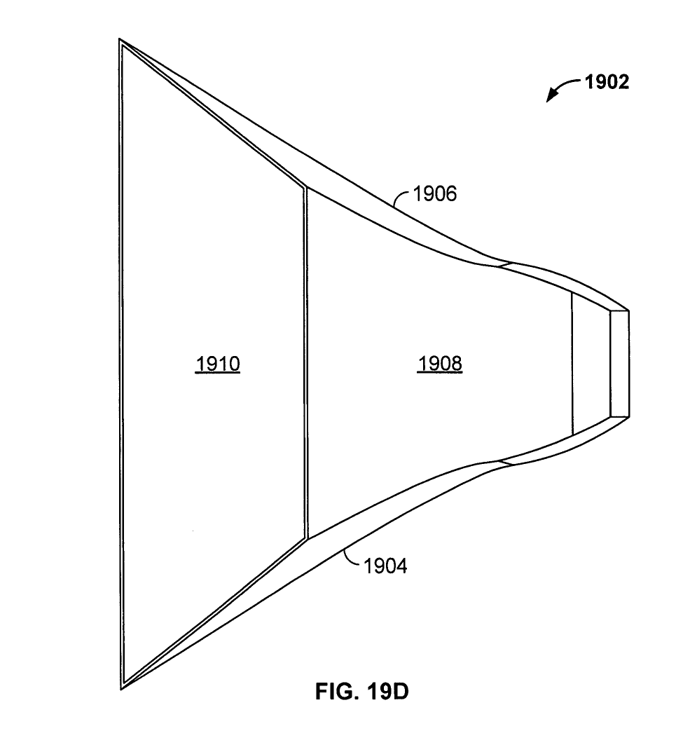

FIG. 19A is a diagram illustrating an embodiment of a secondary optic that is curved in one dimension. Reflective secondary optic 1902 is hollow, comprising four facets 1904, 1906, 1908, and 1910, an exit aperture, and an entry aperture. The exit aperture and the entry aperture are not parallel to each other in this case. Facets 1904, 1906, 1908, and 1910 are each curved in one dimension. Curved in one dimension means that a flat surface, such as a flat piece of sheet metal, is curved such that there is a radius of curvature describing the curve and lines parallel to the axis of curvature do not pass through the plane. The axis of curvature is the line about which the surface is bent. For example, if a flat piece of paper is bent along a line, the line is the axis of rotation. In the case of multiple curves in the same one dimension, the axes of curvature of the curves are parallel. For example, looking at the edge of a flat sheet curved in one dimension, along any axis of curvature, only the edge of the sheet will be visible, not the surface.

The interior of secondary optic 1902 is reflective. Solar energy is received at the entry aperture, reflected from the interior surface and the reflected energy is output from the exit aperture. A receiver (e.g., a solar cell) may be placed at or near the exit aperture such that it receives the energy output from the exit aperture.

Secondary optic 1902 is an alternative embodiment to secondary optic 924 and has similar functional properties to secondary optic 924. Materials, layers, and/or coatings that may be used in secondary optic 1902 are similar to those that may be used in secondary optic 924. Tabs and tab slots may be used to attach each of the facets in this embodiment (or in any of the embodiments described herein) to each other, similar to in secondary optic 924.

Thus, secondary optic 1902 provides a variety of benefits, including: lower cost of manufacture compared to transmissive secondary optics; a capability to pre-coat reflective surfaces prior to forming, thus reducing overall cost; and reduced loss of reflective surface area at the bends or joints (mating edges). The design of 1902 avoids tight bends, which can cause cracks in the surface. Tight bends are also potential reliability failure points since the material is more likely to fatigue at the tight bend and allow crack formation or easier propagation of water or humidity. Loose bending also avoided by 1902, would avoid cracking but would cause too much loss of light. Butting the edges together such as described reduces losses, avoids cracking and is an easy manufacturing process.

FIGS. 19B-19D show a front view, side view, and top view, respectively, of secondary optic 1902.

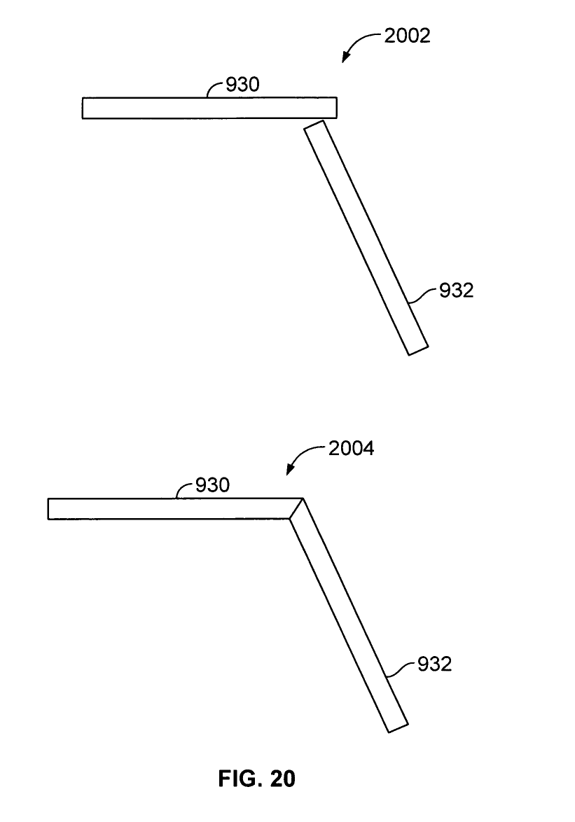

FIG. 20 is a diagram illustrating an embodiment of edge preparation in a secondary optic. In this example, diagram 2002 shows a cross section of a portion of facets 930 and 932 of secondary optic 924 in FIG. 9. As shown, there is a small gap between facet 930 and facet 932 where the two facets contact or butt against each other. This small gap may lead to undesirable effects on the reflectivity of in the interior surface of secondary optic 924. The small gap can be eliminated by mitering the edges of facet 930 and facet 932 as shown in diagram 2004. Mitering in this example refers to making the edges of facets 930 and 932 angled so that the edges are flush with each other where the two facets contact each other. Any of the embodiments described herein may include one or more mitered parts, e.g., for the purpose of improving the reflectivity of the secondary optic.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A solar power system, comprising:
a solar energy receiving solar collector;
a reflective secondary optical element comprising one or more sheets, wherein the one or more sheets are arranged to form a hollow structure having an interior surface, an exterior surface, an entry aperture, and an exit aperture, such that at least a portion of the interior of the hollow structure is reflective and wherein the hollow structure is positioned to receive energy from the solar collector through the entry aperture, reflect the energy from the interior surface of the hollow structure, and output the reflected energy through the exit aperture; and
a receiver positioned to receive the reflected energy from the exit aperture;
whereby the energy from the solar collector is reflected and thereby directed through the exit aperture to the receiver by the reflective secondary optical element.

2. A system as recited in claim 1, wherein at least one sheet is flat.

3. A system as recited in claim 1, wherein at least one sheet is curved in one dimension.

4. A system as recited in claim 1, wherein at least one sheet comprises silver.

5. A system as recited in claim 1, wherein at least one sheet comprises metal.

6. A system as recited in claim 1, wherein at least one sheet comprises aluminum.

7. A system as recited in claim 1, wherein at least one sheet comprises anodized aluminum.

8. A system as recited in claim 1, wherein at least one sheet is coated to increase reflectivity.

9. A system as recited in claim 1, wherein at least one sheet is coated to provide environmental protection.

10. A system as recited in claim 1, wherein at least one sheet has a dielectric coating.

11. A system as recited in claim 1, wherein at least one sheet has a mitered edge.

12. A system as recited in claim 1, wherein none of the sheets includes bends.

13. A system as recited in claim 1, wherein the structure comprises four facets.

14. A system as recited in claim 1, wherein the structure comprises eight facets.

15. A system as recited in claim 1, wherein two sheets are joined using at least one tab.

16. A system as recited in claim 1, wherein the interior surface does not include a bend.

17. A system as recited in claim 1, wherein the exit aperture and an active area of the receiver are spaced apart from each other.

18. A system as recited in claim 1, wherein the structure comprises one sheet arranged in a conical shape.

19. A system as recited in claim 1, wherein the structure includes a shield extending from the entry aperture, wherein the shield is arranged to block energy from reaching a sensitive component.

20. A system as recited in claim 1, wherein the reflective secondary optical element and the receiver are enclosed in a box for protection against the elements.

21. A system as recited in claim 20, wherein the box includes a window arranged to receive energy from the collector and transmit the energy to the reflective secondary optical element.

22. A system as recited in claim 20, wherein the collector is enclosed in the box.

23. A system as recited in claim 1, wherein the receiver is mounted in a manner that avoids shading of the solar collector during operation.

24. A system as recited in claim 1, wherein the reflective secondary optic is mounted in a manner that avoids shading of the solar collector during operation.

25. A system as recited in claim 1, wherein the receiver is a photovoltaic cell.

26. A system as recited in claim 1, further including a platform having a first degree of freedom; and wherein the solar power system is mounted on the platform in a manner such that it has a second degree of freedom relative to the platform.

27. A method of receiving energy, comprising:
receiving energy from a solar energy receiving solar collector through an entry aperture of a reflective secondary optical element comprising one or more sheets, wherein the one or more sheets are positioned to form a hollow structure having an interior surface, an exterior surface, an entry aperture, and an exit aperture, such that at least a portion of the interior of the hollow structure is reflective;
reflecting the energy from the interior surface of the hollow structure;
outputting the reflected energy through the exit aperture; and
receiving the reflected energy from the exit aperture at a receiver;
whereby the energy from the solar collector is reflected and thereby directed through the exit aperture to the receiver by the reflective secondary optical element.
